(19) United States
(12) Patent Application Publication
(10) Pub. No.: US 2004/0021170 A1
(43) Pub. Date: Feb. 5, 2004

(54) Method and apparatus for injecting charge onto the floating gate of a nonvolatile memory cell

(76) Inventor: John M. Caywood, Sunnyvale, CA (US)

Correspondence Address: David B. Ritchie, THELEN REID & PRIEST LLP, P.O. Box 640640, San Jose, CA, 55164-0640, US

(21) Appl. No.: 09/942,338

(22) Filed: Aug. 28, 2001

Related U.S. Application Data
(63) Continuation-in-part of application No. 09/516,400, filed on Mar. 1, 2000, now Pat. No. 6,534,816.
Application No. 09/516,400 is a continuation-in-part of application No. 09/275,168, filed on Mar. 24, 1999, now abandoned.
Application No. 09/516,400 is a continuation-in-part of application No. 09/552,252, filed on Apr. 18, 2000.
Application No. 09/552,252 is a continuation of application No. 09/275,168, filed on Mar. 24, 1999, now abandoned.
Application No. 09/552,252 is a continuation of application No. 09/731,942, filed on Dec. 6, 2000, now Pat. No. 6,479,863.
Application No. 09/731,942 is a continuation of application No. 09/522,252, filed on Mar. 9, 2000, now Pat. No. 6,384,451.

(51) Int. Cl. H01L 29/788

(52) U.S. Cl. 257/315

(57) ABSTRACT

A tunneling charge injector for use with a MOS floating gate nonvolatile memory cell includes a conducting injector electrode, a grid insulator disposed adjacent the conducting injector electrode, a grid electrode disposed adjacent the grid insulator, a retention insulator which may employ a graded band gap disposed adjacent the grid electrode, and a floating gate disposed adjacent said retention insulator. The floating gate of the tunneling charge injector is coupled to or forms a part of the floating gate of the nonvolatile memory element. Charge is injected from the conducting injector electrode onto the floating gate. Electrons are injected onto the floating gate when the conducting injector electrode is negatively biased with respect to the grid electrode; holes are injected onto the floating gate when the conducting injector electrode is positively biased with respect to the grid electrode.

### CROSS-REFERENCE TO RELATED APPLICATION

This application is a continuation-in-part of: (1) co-pending U.S. patent application Ser. No. 09/516,400 filed Mar. 1, 2000 entitled “METHOD AND APPARATUS FOR INJECTING CHARGE ONTO THE FLOATING GATE OF A NONVOLATILE MEMORY CELL” in the name of inventor John M. Caywood, itself a continuation-in-part of U.S. patent application Ser. No. 09/275,168 filed Mar. 24, 1999 (now abandoned) and entitled “METHOD AND APPARATUS FOR INJECTING CHARGE ONTO THE FLOATING GATE OF A NONVOLATILE MEMORY CELL” in the name of inventor John M. Caywood; (2) co-pending U.S. patent application Ser. No. 09/552,252 filed Mar. 9, 2000 entitled “METHOD AND APPARATUS FOR INJECTING CHARGE ONTO THE FLOATING GATE OF A NONVOLATILE MEMORY CELL” in the name of inventor John M. Caywood, itself a continuation of U.S. patent application Ser. No. 09/275,168, and (3) co-pending U.S. patent application Ser. No. 09/731,942 filed Dec. 6, 2000 entitled “METHOD AND APPARATUS FOR INJECTING CHARGE ONTO THE FLOATING GATE OF A NONVOLATILE MEMORY CELL” in the name of inventor John M. Caywood, itself a continuation of U.S. patent application Ser. No. 09/522,252, all commonly owned herewith.

### BACKGROUND OF THE INVENTION

1. Field Of The Invention

The present invention relates to nonvolatile memory. More particularly, the present invention relates to methods and apparatus for injecting electrons and holes onto the floating gate of a floating gate MOS transistor nonvolatile memory cell.

2. The Background

Nonvolatile memories employing floating gate technology have found wide use in a variety of applications, and have become an increasingly important type of semiconductor nonvolatile memory. In a floating gate nonvolatile memory, the floating gate electrode of a MOS transistor is electrically isolated from neighboring electrodes by a high quality dielectric that surrounds the floating gate. The contents of the memory, e.g. whether a ‘0’ or a ‘1’ in a digital memory, is determined by the amount of charge on the floating gate.

In a memory known to those of ordinary skill in the art as flash memory, electrons are commonly added to the floating gate by a process of hot electron injection that is controlled by the bias applied to various elements of the floating gate transistor. To remove electrons from the floating gate, electrons tunnel from the floating gate to surrounding electrodes under the influence of a high electric field. In the most common form of this technology, the electrons are caused to tunnel from the floating gate to an underlying silicon region by applying a bias across a relatively thin layer of silicon dioxide. For the charge to be retained on the floating gate for an extended period of time, it is important that the tunneling operate in what is referred to by those of ordinary skill in the art as the Fowler-Nordheim mode so that the current under cell storage and read conditions is very low, typically less than 10⁻¹⁵ A/cm².

It has been demonstrated that to restrict tunneling to the Fowler-Nordheim mode, the oxide through which the electrons tunnel should be thicker than about 5 nanometers. Further, the 5 nm lower bound is not a practical limit because the act of applying the voltage across the oxide to cause tunneling damages the oxide. To reduce the stress induced leakage current that occurs due to the damage to the oxide, the minimum oxide thickness should be increased from the lower bound of about 5 nm to about 8 nm. (See Naruke, K., et al, “Stress Induced Leakage Current Limiting to Scale Down EEPROM Tunnel Oxide Thickness”, IEDM Tech. Digest pp. 424-7 (1988)).

As integrated circuit (IC) dimensions have been scaled below 0.25 μm, the operating voltages of-CMOS circuits have also been scaled down. Unfortunately, it has been demonstrated that the applied voltages typically employed to inject electrons onto and tunnel off of the floating gate of an electrically erasable programmable read only memory (EEPROM) are not capable of being scaled down to the same degree as the operating voltages of below 0.25 μm processes. (See Yoshikawa, K. et al, “Flash EEPROM Cell Scaling Based on Tunnel Oxide Thinning Limitations”, Symp. on VLSI Technol. Dig. Tech. Papers, pp. 79-80 (1991); Yamaguchi, Yoshiko, et al, “ONO Interpoly Dielectric Scaling Limit for Non-volatile Memory Devices”, Symp. on VLSI Technol. Dig. Tech. Papers, pp. 85-86 (1993); and Caywood, J. M. and Gary Derbenwich “Nonvolatile Memories”, in ULSI Device Technology, pp. 377-470, Eds. C. Y. Chang and S M Sze, John Wiley & Sons, New York (2000).

Because charge leakage through the tunnel oxide limits the scaling of the tunnel oxide thickness and the physics of the phenomena used for injecting charge onto the floating gate limit the scaling of the voltages, it is well understood in the art that the mismatch between the minimum physical dimensions and minimum operating voltages of the floating gate nonvolatile memories and the surrounding CMOS logic technology is becoming increasingly acute. Accordingly, what is needed are new apparatus and methods for charging and discharging the floating gate so that the physical dimensions and required voltages can be reduced to values more compatible with CMOS logic technology.

### BRIEF DESCRIPTION OF THE INVENTION

A tunneling charge injector that includes a conducting injector electrode, a grid insulator disposed adjacent the conducting injector electrode, a grid electrode disposed adjacent the grid insulator, a retention insulator disposed adjacent the grid electrode, and a floating gate disposed adjacent the retention insulator, may be employed to inject charge from the conducting injector electrode onto a floating gate.

In one aspect of the present invention, the tunneling charge injector may be employed to inject both electrons and holes onto the floating gate electrode. Electrons are injected onto the floating gate when the conducting injector electrode is sufficiently negatively biased with respect to the grid electrode and the floating gate is biased to collect electrons into the grid. Holes are injected onto the floating gate when the conducting injector electrode is sufficiently positively biased with respect to the grid electrode and the floating gate is biased to collect electrons into the grid.

In another aspect of the present invention, separate tunneling electron and hole injectors may be employed to inject electrons or holes onto the floating gate. Electrons are injected onto the floating gate when the conducting injector electrode is sufficiently negatively biased with respect to the grid electrode and the floating gate is biased to collect electrons into the grid. Holes are injected onto the floating gate when the conducting injector electrode is sufficiently positively biased with respect to the grid electrode and the floating gate is biased to collect electrons into the grid.

In another aspect of the present invention, the tunneling charge injector may be employed in a nonvolatile memory cell having a nonvolatile memory element with a floating gate such as a floating gate MOS transistor. In the nonvolatile memory cell, the floating gate of the tunneling charge injector is coupled to or forms a part of the floating gate of the nonvolatile memory element. The tunneling charge injector is employed to inject charge onto the floating gate of the nonvolatile memory element.

In another aspect of the present invention, separate tunneling electron and hole injectors may be employed in a nonvolatile memory cell having a nonvolatile memory element with a floating gate such as a floating gate MOS transistor. In the nonvolatile memory cell, the floating gates of the separate tunneling electron and hole injectors are coupled to or form a part of the floating gate of the nonvolatile memory element. The tunneling electron injector is employed to inject electrons onto the floating gate of the nonvolatile memory element, and the tunneling hole injector is employed to inject holes onto the floating gate of the nonvolatile memory element. Injection may be performed ballistically, i.e., without significant scattering.

In another aspect of the present invention, a memory device includes an array of nonvolatile memory cells wherein each of the memory cells comprises a nonvolatile memory element with a floating gate such as a floating gate MOS transistor and a tunneling charge injector having a floating gate that is either coupled to the floating gate of the nonvolatile memory element or forms a portion of the floating gate of the nonvolatile memory element.

In another aspect of the present invention, a memory device includes an array of nonvolatile memory cells wherein each of the memory cells comprises a nonvolatile memory element with a floating gate such as a floating gate MOS transistor, a tunneling electron injector having a floating gate that is either coupled to the floating gate of the nonvolatile memory element or forms a portion of the floating gate of the nonvolatile memory element, and a tunneling hole injector having a floating gate that is either coupled to the floating gate of the nonvolatile memory element or forms a portion of the floating gate of the nonvolatile memory element.

In another aspect of the present invention the tunneling charge injectors and memory devices described herein are equipped with a retention insulator featuring a first band gap in a first portion of said retention insulator disposed adjacent to said grid electrode and a second, greater band gap in a second portion of said retention insulator disposed between said grid electrode and said floating gate to facilitate charge injection.

In yet another aspect of the present invention, the hole current to parasitic electron current ratio in a device using a p+ Si injector and a p+ Si grid electrode can be controlled to a value greater than one by appropriate choice of the dielectric (grid insulator) disposed between the injector and the grid.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIGS. 1a, 1b and 1c are, respectively, electrical schematic symbols a for tunneling charge injector, a tunneling electron injector, and a tunneling hole injector, in accordance with the present invention.

FIGS. 2a, 2b and 2c are, respectively band diagrams of a tunneling charge injector in the (a) flat band condition and (b) under bias for injection of electrons and (c) holes in accordance with a specific embodiment of the present invention.

FIGS. 3a, 3b and 3c are respectively, band diagrams of a tunneling electron injector in the (a) flat band condition and (b) under bias for injection of electrons in accordance with a specific embodiment of the present invention.

FIGS. 4a and 4b are, respectively, band diagrams of a tunneling hole injector in the (a) flat band condition and (b) under bias for injection of holes in accordance with a specific embodiment of the present invention.

FIGS. 5a and 5b are respectively, band diagrams of a tunneling hole injector in the (a) flat band condition and (b) under bias for injection of holes in accordance with a specific embodiment of the present invention.

FIG. 6a is an electrical schematic diagram illustrating a tunneling charge injector coupled to a floating gate MOS transistor to form a nonvolatile memory element in accordance with a specific embodiment of the present invention.

FIG. 6b is an electrical schematic diagram illustrating a tunneling electron injector and a tunneling hole injector coupled to a floating gate MOS transistor to form a nonvolatile memory element in accordance with a specific embodiment of the present invention.

FIG. 7 is an electrical schematic diagram illustrating a portion of an array of the nonvolatile memory elements depicted in FIG. 6a in accordance with a specific embodiment of the present invention.

FIG. 8 is an electrical schematic diagram illustrating a portion of an array of the nonvolatile memory elements depicted in FIG. 6b in accordance with a specific embodiment of the present invention.

FIGS. 9a, 9b, 10a, 10b, 11a-11d, 12a-12d, 13a-13d, 14a-14d, 15a-15d, 16a-16d, 17a-17e, and 18a-18e illustrate selected steps in the fabrication of a portion of the array of nonvolatile memory elements depicted in FIG. 8 in accordance with a specific embodiment of the present invention.

FIG. 19 is a band diagram of a retention insulator having a graded band gap in accordance with a specific embodiment of the present invention.

FIG. 20a is a plot showing relative permittivity and fractional oxide content of an SiOₓN_{y} film deposited on an SiO₂ film in accordance with a specific embodiment of the present invention.

FIG. 20b is a plot showing the variation of the electrical potential and the conduction band edge for the structure plotted in FIG. 20a.

FIG. 21a is a band diagram of a tunneling electron injector having retention insulator formed of SiOₓN_{y} having a non-graded band gap in the flat band condition.

FIG. 21b is a band diagram of the structure of FIG. 21 a under bias for injection of electors showing an undesirable potential wall.

FIGS. 22a, 22b and 22c are, respectively, band diagrams of a tunneling charge injector having a graded band gap in the (a) flat band condition and (b) under bias for injection of electrons and (c) holes in accordance with a specific embodiment of the present invention.

FIG. 23 is an electrical schematic diagram of an array of non-volatile memory elements in accordance with an alternative specific embodiment of the present invention.

FIG. 24 is a plot of current density vs. bias as calculated for a p+ silicon injector with a p+ silicon grid electrode.

FIG. 25 is a plot of potential energy vs. fraction oxide showing the variation of band edges in the SiOₓN_{y} system as a function of the relative oxide concentration.

FIG. 26 is a plot of energy difference vs. fraction oxide for the system of FIG. 25 illustrating that the tunneling energy barrier for holes becomes less than that for electrons from the valence band when the oxide fraction is less than about 77%.

FIG. 27 is plot of current vs. applied bias from the injector to the grid comparing the calculated value of the hole current to that of the parasitic electron current for a dielectric having 70% oxide.

FIG. 28a is a layout view of a floating gate nonvolatile memory device in accordance with one embodiment of the present invention.

FIG. 28b is a cross-sectional view taken along line B-B′ of FIG. 28a.

FIG. 28c is a cross-sectional view taken along line A-A′ of FIG. 28a.

FIGS. 29a, 29b, 30a, 30b, 31a, 31b, 31c, 32a, 32b and 32c illustrate selected steps in the fabrication of a portion of the array of nonvolatile memory elements depicted in FIG. 33 in accordance with one embodiment of the present invention.

FIG. 33 is an electrical schematic diagram illustrating a portion of an array of the nonvolatile memory elements depicted in FIGS. 28a, 28b and 28c in accordance with one embodiment of the present invention.

### DETAILED DESCRIPTION OF A PREFERRED EMBODIMENT

Embodiments of the present invention are described herein in the context of a nonvolatile memory cell and arrays of such cells. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

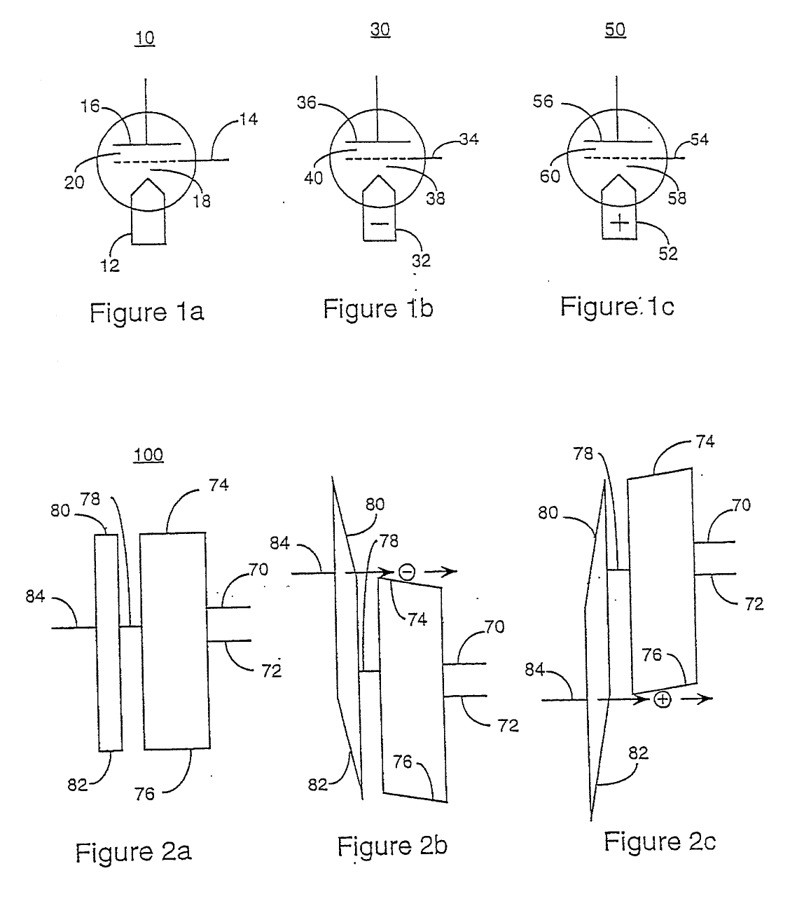

In FIG. 1a, the electrical circuit symbol for a tunneling charge injector 10, according to the present invention, suitable for delivering either electrons or holes to the floating gate of a nonvolatile memory is illustrated. In FIG. 1b, the electrical circuit symbol for a tunneling electron injector 30, according to the present invention, suitable for delivering electrons to the floating gate of a nonvolatile memory is illustrated. In FIG. 1c, the electrical circuit symbol for a tunneling hole injector 50, according to the present invention, suitable for delivering holes to the floating gate of a nonvolatile memory is illustrated. The implementation of the tunneling charge injector 10, tunneling electron injector 30 and tunneling hole injector 50, according to the present invention, will be discussed in detail below.

The tunneling charge injector 10 has a conducting injector electrode 12, a grid electrode 14, and a floating gate 16 (sometimes referred to as a floating gate electrode). Disposed between the injector electrode 12 and the grid electrode 14 is a grid insulator 18, and disposed between the grid electrode 14 and floating gate 16 is a retention insulator 20. The tunneling electron injector 30 has a conducting injector electrode 32, a grid electrode 34, and a floating gate 36. Disposed between the injector electrode 32 and the grid electrode 34 is a grid insulator 38, and disposed between the grid electrode 34 and floating gate 36 is a retention insulator 40. The tunneling hole injector 50 has a conducting injector electrode 52, a grid electrode 54, and a floating gate 56. Disposed between the injector electrode 52 and the grid electrode 54 is a grid insulator 58, and disposed between the grid electrode 54 and floating gate 56 is a retention insulator 60.

In the tunneling charge injector 10, a bias is applied so that charge is emitted from the conducting injector electrode 12 with sufficient energy to pass through grid insulator 18, grid electrode 14, and a retention insulator 20 to be collected by the floating gate 16. To charge the floating gate 16, electrons are injected by tunneling into the grid electrode 14 from which they are collected on the floating gate 16, and to discharge the floating gate 16, holes are injected by tunneling into the grid electrode 14 from which they are collected on the floating gate 16.

In the tunneling electron injector 30, a bias is applied so that electrons are emitted from the conducting injector electrode 32 with sufficient energy to pass through grid insulator 38, grid electrode 34, and the retention insulator 40 to be collected by the floating gate 36.

In the tunneling hole injector 50, a bias is applied so that holes are emitted from the conducting injector electrode 52 with sufficient energy to pass through grid insulator 58, grid electrode 54, and the retention insulator 60 to be collected by the floating gate 56.

A tunnel emission amplifier implemented with a triode structure that is somewhat similar to the tunneling charge injector 10, the tunneling electron injector 30, and the tunneling hole injector 50 was disclosed by Mead in “The Tunnel Emission Amplifier”, Proceedings of the IRE, Vol. 48, pp. 359-361 March 1960. In the triode structure described by Mead, a first Al layer forms an emitter, a layer of Al₂O₃ is disposed on the emitter, a thin second Al layer disposed on the Al₂O₃ layer forms a base, a layer of SiO formed on the thin Al base, and a third Al layer disposed on the layer of SiO forms a collector. In operating this structure as a tunnel emission amplifier, a bias is applied from the emitter to the base to tunnel electrons from the emitter to the base through the first insulating layer. Metals were chosen as a carrier source because the electron densities are very large.

As will described below, the thicknesses and physical properties of the grid insulator 18 and retention insulator 20 can be separately optimized for the tunnel injection and charge retention functions, and the conducting injector electrode 12 and floating gate 16 can also be chosen to optimize the efficiency of the injection phenomenon. Further, the tunneling charge injector 10 can be used for to provide both holes and electrons to simplify the fabrication process or the structures for injection and collection of electrons and holes by the tunneling electron injector 30 and tunneling hole injector 50, respectively, can be optimized separately.

Turning now to FIG. 2a, a bandgap diagram of a tunneling charge injector 10 according to the present invention is illustrated. In this embodiment, the floating gate 16 is composed of silicon having a conduction band edge 70 and a valence band edge 72. Formed next to the floating gate 16 is the retention insulator 20 having a conduction band edge 74 and valence band edge 76. The retention insulator 20 is preferably formed thick enough and with a material having a large enough band gap to effectively keep charges from leaking from the floating gate 16. In a specific embodiment, the retention insulator 20 is silicon oxide having a thickness of between about 8 nm and about 50 nm, and preferably between about 15 nm to about 20 nm.

The grid electrode 14 is formed adjacent the retention insulator 20 to serve as an electrode for tunneling, and is preferably thin enough to minimize the loss of energy of injected charge carriers, but thick enough to conduct away the charge carriers that lose energy and are thermalized in the grid electrode 14. In a specific embodiment, a metal with a work function with a fermi level 78 that lies in the middle of the silicon band gap in the flat band condition is chosen for the grid electrode 14. Cr (chromium), Ni (nickel), Cu (copper), and W (tungsten) are examples of metals that approximately meet this criterion. The grid electrode 14 has a thickness of about 10 nm to about 50 nm thick and is preferably in the range of about 15 nm to about 20 nm.

The grid insulator 18 formed adjacent the grid electrode 14 has a conduction band edge 80 and valence band edge 82. The grid insulator 18 is silicon dioxide having a thickness in the range of about 2 nm to about 6 nm and preferably in the range of about 2 nm to about 4 nm in a specific embodiment. The thickness of the grid insulator 18 is selected to permit charge carriers to tunnel through with the application of a modest voltage in the range of about 2 V to about 6 V and preferably in the range of about 3 V to about 5 V across the grid insulator 18.

The conducting injector electrode 12 formed adjacent the grid insulator layer 18 has fermi level 84. In a specific embodiment, a metal employed in the conducting injector electrode 12 has a work function similar to that of the metal forming the grid electrode 14.

There are several considerations that should be taken into account in selecting the grid material. An absolute requirement is that the material be compatible with integrated circuit processing. It is desirable that the mean free path of the injected carriers in the grid be relatively long so that they experience little or no scattering. This is referred to a “ballistic injection”. It is also desirable that the grid and injector materials be chosen so that the parasitic back injection of a carrier from the grid to the injector be less than the desired carrier injection from the injector to the grid. For example, if the grid and injector are biased to cause hole injection from the injector to the grid, it is desirable that the tunnel current of electrons from grid to injector should be less than the hole current from the injector to the grid. For carriers of a given type, the requirements of reduced parasitic tunnel current and increased mean free path can be optimized simultaneously by selecting materials with Fermi levels closer to the band edge in the grid insulator for that carrier type, i.e. for electrons choose materials with Fermi level closer to the grid conduction band. This increases the energy barrier for hole injection and reduces the energy of the electrons in the grid with respect to the Fermi level. The range of hot carriers in metals is known to decrease exponentially with increased energy above the Fermi level. If a single material is to be used for the grid for both holes and electrons, judicious compromises must be made.

For the embodiment of the tunneling charge injector 10 described with respect to FIG. 2a, the application of a negative bias from the injector electrode 12 with respect to the grid electrode 14, as illustrated in FIG. 2b, will result in electrons tunneling from the injector electrode 12 to the grid electrode 14. When the injector electrode 12 is more than about 3.8 V negative with respect to the grid electrode 14, some of the injected electrons will reach the interface between the grid electrode 14 and the retention insulator 20 with enough energy to surmount the energy barrier of the retention insulator 20. When the potential of the floating gate 16 is positive with respect to the potential of the grid electrode 14, most of the electrons that surmount the energy barrier of the retention insulator 20 will be collected on the floating gate 16. In this manner, the floating gate 16 is charged negatively. A potential of about 0.5 V to about 1 V between grid electrode 14 and floating gate 16 is sufficient for the collection of electrons on the floating gate 16. It should be appreciated that larger potentials have the beneficial effect of lowering the energy barrier of the retention insulator 20.

As is illustrated in FIG. 2c, when the potentials applied to tunneling charge injector 10 depicted in FIG. 2a are reversed in polarity, holes can be injected onto the floating gate 16 to charge the floating gate 16 positively. For the specific embodiment of FIG. 2a, a positive bias of about 5.8 V between grid electrode 14 and injector electrode 12 is required for the injected holes to have enough energy to surmount the grid insulator 18. The magnitude of the bias required between the floating gate 16 and the grid electrode 14 to collect holes injected over the potential barrier of the retention insulator 20 is about 0.5 V to about 1 V. This is similar to the case of electron injection. Thus, a total voltage drop of 7 V between the injector electrode 12 and the floating gate 16 is sufficient to cause holes to be injected onto the floating gate 16.

The injection efficiency, i.e. the fraction of carriers injected from the injector electrode 12 that reach the floating gate 16, is expected to be between 0.1% and 1% for an electron injector and perhaps an order of magnitude lower for a hole injector. These efficiencies are several orders of magnitude greater than those of a typical channel hot electron flash EEPROM.

By implementing the injector conductor 12 with materials other than those disclosed with respect to the embodiment of FIG. 2a, the injection efficiencies may be improved and the required applied voltages may be reduced.

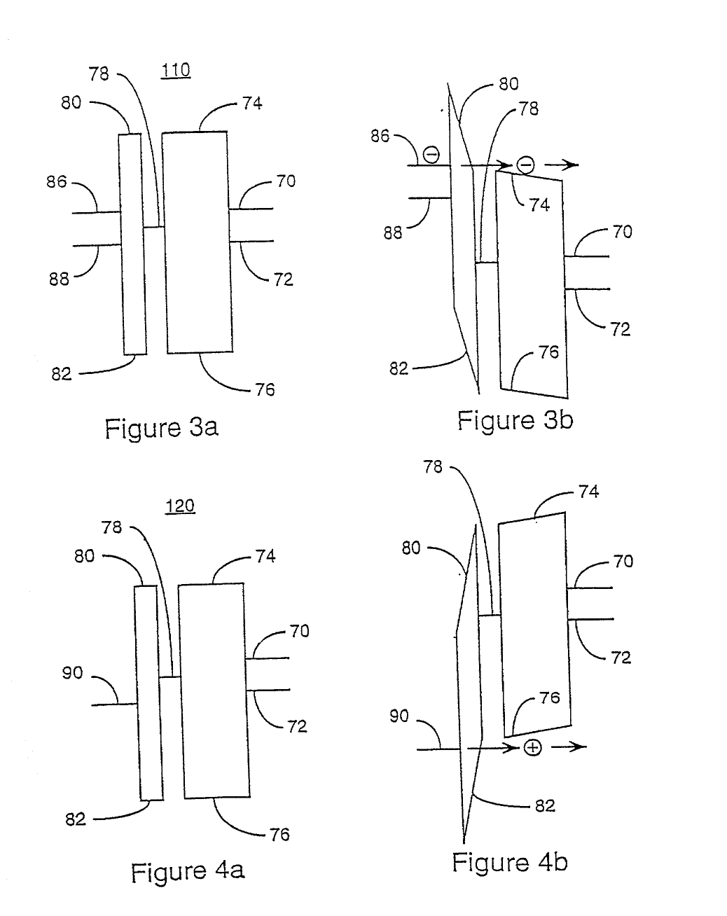

FIG. 3a illustrates a conduction band diagram for tunneling electron injector 30 as depicted in FIG. 1b. The conduction band diagram of FIG. 3a is similar to that of FIG. 2a, except that the injector electrode 32 is a heavily doped n-type silicon having a conduction band edge 86 and valence band edge 88. In FIG. 3b, the structure depicted in FIG. 3a, has been biased to inject electrons. In contrast to the structure of FIG. 2a, because electrons can be injected from the conduction band edge 86, the bias between the injector electrode 32 and the grid electrode 34 can be reduced to about 3.2 V. Moreover, due to the band gap of silicon, there are essentially no states available for tunneling that are more than 1 eV below the conduction band edge. This reduces the tunneling probability of lower energy electrons. This is advantageous because these lower energy electrons do not effectively contribute to the charge on the floating gate 36, but rather only add to the current in the grid electrode 34.

Those of ordinary skill in the art will appreciate from the discussion in the previous paragraph that use of an electron injector composed of an electropositive material results in a larger injector current for a given electric field applied across the grid insulator than would be the case if the injector material were to be more electronegative. This is advantageous because lower electric field should have a reduced rate of wear out. On the other hand, it is also well known to those of ordinary skill in the art that many electropositive elements are not suitable for use in integrated circuit technology because they are too reactive, diffuse too rapidly, or are possessed of too low a melting temperature. Among those elements that are expected to be useful are aluminum (Al), titanium (Ti), vanadium (V), manganese (Mn), zirconium (Zr), tantalum (Ta), niobium (Nb) and n-type silicon.

FIG. 4a illustrates a conduction band diagram for tunneling hole injector 50 as depicted in FIG. 1c. The conduction band diagram of FIG. 4a is similar to that of FIG. 2a, except that the injector electrode 52 is a metal with a large work function such as Pt (platinum) having a fermi level 90. Further, Pt may be employed as a metal in the grid electrode 54 in addition to the metals disclosed for the grid electrode in FIG. 2a. In FIG. 4b, the structure depicted in FIG. 4a, has been biased to inject holes over the barrier of retention insulator into the valence band of the retention insulator. For this structure, the bias required for hole injection over the retention insulator with respect to the flat band condition is reduced to about 4.4 V. Those of ordinary skill in the art will now recognize that other such materials in addition to Pt would also work. Examples include iridium (Ir), palladium (Pd), p-type silicon and the like.

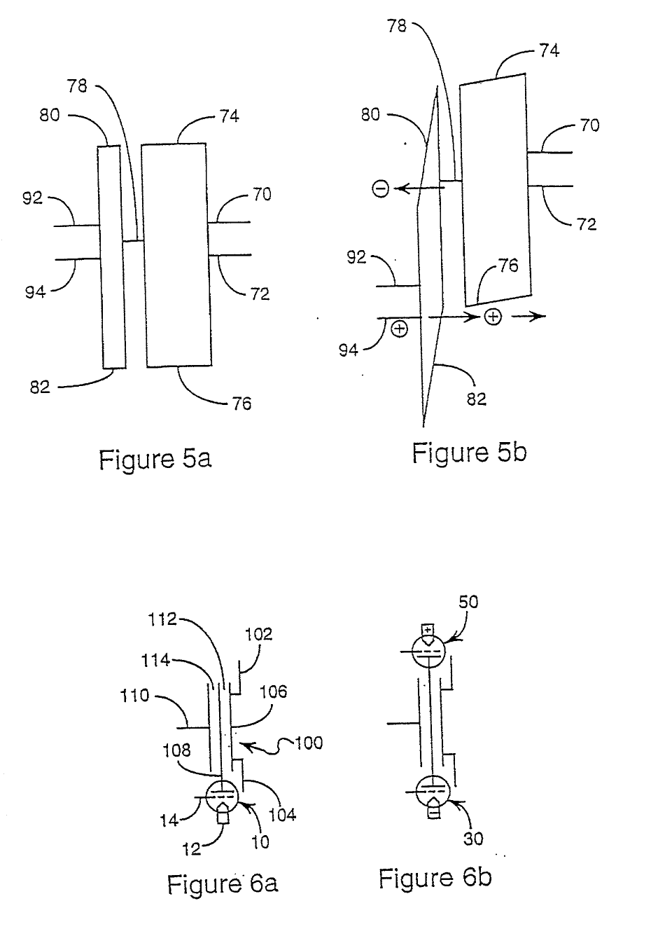

FIG. 5a illustrates a conduction band diagram for an alternative embodiment of the tunneling hole injector 30 as depicted in FIG. 1c. The conduction band diagram of FIG. 5a is similar to that of FIG. 2a, except that the injector electrode 52 is a heavily doped p-type silicon having a conduction band edge 92 and valence band edge 94. In FIG. 5b, the structure depicted in FIG. 5a, has been biased to inject holes. The bias depicted in FIG. 5b for injection of holes into the conduction band of the retention insulator is about 4.6 V. Similar to n-type silicon electron injector depicted in FIG. 3a, there is a band gap of greater than 1 eV above the valence band edge for which there are essentially no states from which low energy holes can tunnel into the grid electrode 54 and contribute to the grid current. This leads to increased efficiency of hole injection onto the floating gate 56.

Further as depicted in FIG. 5b the material of the grid electrode may be selected to improve the efficiency of the tunneling hole injector 50. One consideration in selecting the material is the range of the hot carrier in the grid material. It is desirable that this range be maximized. Another consideration is to decrease the tunneling of unwanted electrons. As illustrated in FIG. 5b, while tunneling holes from the valence band of the p-type silicon emitter, electrons will tunnel from near the fermi level 96 in the grid electrode 54 into the conduction band in the injector electrode 52. This can be greatly reduced by using a grid material that has a larger work function.

From the discussion above, it should be appreciated by those of ordinary skill in the art that the selection of the insulating layers may also increase the injection efficiency. For example, if present efforts to develop silicon nitride with low density of traps so that Poole-Frenkel conduction is suppressed is successful, nitride might be beneficially employed for the retention insulator because it has a lower energy barrier to injection of both electrons and holes than silicon oxide. Further, although silicon dioxide is preferably employed as the grid insulator, it should be appreciated by those of ordinary skill in the art that other wide band gap insulators, such as aluminum oxide may be suitably employed as the grid insulator.

It should also be appreciated by those of ordinary skill in the art that a semiconductor may be employed as the grid material. It is appreciated by those of ordinary skill in the art that electron-electron scattering is the principle loss mechanism for hot electrons in metal. The range of electrons with a few electron volts of energy may be longer in semiconductors due to a lower carrier concentration. A longer mean free path would give rise to a higher efficiency and thereby provide a lower grid current that is lower than for metals. The higher efficiency offsets the larger resistivity effects found in a semiconductor in comparison to a metal.

In FIGS. 6a and 6b, a typical floating gate MOS transistor 100 having a source 102 and a drain 104 formed in a semiconductor body 106, a floating gate 108, a control gate 110, and first and second insulating layers 112 and 114 is illustrated. In the floating gate MOS transistor 100, the semiconductor body 106 has a doping of a first type, and the source 102 and drain 104 having a doping of a second type. The source 102 and drain 104 are spaced apart to form a channel region. The floating gate 108 is disposed A above the channel region, and the first insulating layer 112 forming a floating gate dielectric is disposed between the floating gate 108 and the semiconductor body 106. The second insulating layer 114 forming a control gate dielectric is disposed between the control gate 110 and the floating gate 108. In most high density floating gate nonvolatile memory arrays the control gate 110 lies at least partially over the floating gate 108, but is separated from it by second insulating layer 114.

In the operation of the floating gate MOS transistor 100, the potential on the floating gate 108 controls the current flow between the source 102 and drain 104 as is well known to those of ordinary skill in the art. The control gate 110 is an electrode that is capacitively coupled to the floating gate 108 in order to be able to control the current flow through the floating gate MOS transistor 100 with an external bias.

In FIG. 6a, the tunneling charge injector 10 is coupled to the floating gate 108 of the floating gate MOS transistor 100. In FIG. 6b, the tunneling electron injector 30 and the tunneling hole injector 50 are both coupled to the floating gate 108 of the floating gate MOS transistor 100. In specific embodiments of the present invention the floating gate 108 of the floating gate MOS transistor 100 forms the floating gates 16, 36 and 56 of the tunneling charge injector 10, the tunneling electron injector 30 and the tunneling hole injector 50, respectively.

It will be readily appreciated by those of ordinary skill in the art that many subtle arrangements of the elements of the floating gate MOS transistor 100 are well known. The floating gate MOS transistor 100 illustrated in FIGS. 6a and 6b is a generic depiction to illustrate that the tunneling charge injector 10, tunneling electron injector 30 and tunneling hole injector 50 of the present invention may be coupled to various alternative embodiments of floating gate MOS transistors known to those of ordinary skill in the art.

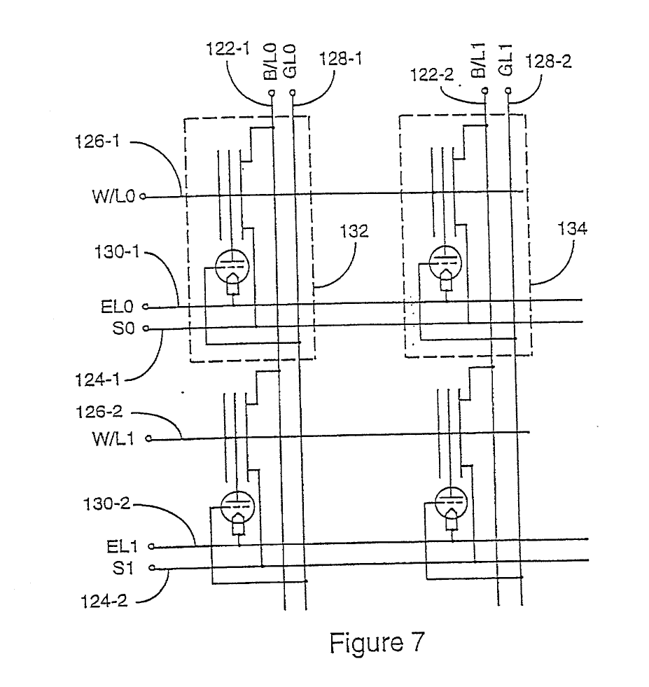

FIG. 7 illustrates a portion of a nonvolatile memory array 120 according to the present invention. Each memory element in the array 120 is a floating gate MOS transistor 100 coupled to a tunneling charge injector 10 as depicted in FIG. 6a. Although the floating gate MOS transistors 100 are n-channel, those of ordinary skill in the art will readily appreciate that they could also be p-channel. Each memory element is connected to a bit line 122, a source line 124, a word line 126, a grid line 128, and an injector line 130. In the portion of a nonvolatile memory array 120, four cells are arranged as two rows and two columns. There are two bit lines 122-1 and 122-2, two source lines 124-1 and 124-2, two word lines 126-1 and 126-2, two grid lines 128-1 and 128-2, and two injector lines 130-1 and 130-2.

In a specific embodiment, the word line 126 is separated from the floating gate of the floating gate MOS transistor 100 on the top and two sides in the word line direction by an ONO layer with an effective oxide thickness of about 20 nm, the tunneling charge injector 10 is formed on one of the other two sides of the floating gate with the grid separated from the floating gate with an oxide layer of about 20 nm thick. The gate oxide the floating gate MOS transistor 100 is about 6 nm thick, and the floating gate is 0.1 μm long, 0.1 μm wide, and 0.15 nm high. Accordingly, the floating gate MOS transistors 100 have a threshold voltage of about 0.4 to about 0.5 V.

In some array architectures, some of the lines of the same type may be connected in parallel. For example, the source lines 124 are commonly connected in parallel to form one equipotential array source. It is also possible for different types of lines to be connected together. For example, in some array configurations, the source lines 124 and injector lines 130 in the same row might share the same potential. It is preferred that the grid and injector lines 128 and 130, respectively, be orthogonal to each other.

During a read operation performed on the memory cells of the array 120, the grid and injector lines 128 and 130, respectively, are biased so that a flat band condition exists between them to prevent current flow. For the embodiment of the tunneling charge injector 10 of FIG. 2a employed with MOS floating gate transistor 100 that is an N-channel device, the source lines 124, unselected word lines 126, grid lines 128, and injector lines 130 are biased at ground during the read operation. The selected word line 130 is biased at a reference potential of about 2.5 V.

With these conditions, the programming bias, erase bias and threshold of a neutrally charged floating gate are chosen so that both programmed and erased floating gate MOS transistors in the array 120 are nonconducting when the word line 130 to which they are coupled is grounded. The erased floating gate MOS transistors in the array 120, but not the programmed transistors floating gate MOS transistors in the array 120, should be conducting when the selected word line 130 is biased at the selected reference potential of about 2.5 V. As is well understood by those of ordinary skill in the art, the threshold of the neutrally charged floating gate of typically about 0.4 V to about 0.5 V is related to the floating gate oxide thickness, floating gate work function, and the doping of the channel regions in the floating gate MOS transistor.

To selectively program the cell in the array 120 indicated by reference numeral 132, injector line 130-1 is biased at about −3 V, the grid line 128-1 is biased at about +1V, and the word line 126-1 is biased at about 5 V. Under these conditions, the grid electrode 14 is about 4 V positive with respect to the injector electrode 12. This bias provides some electrons with enough energy to surmount the energy barrier between the grid electrode 14 and the retention insulator 20. Because the word line 126-1 is biased at 5 V, the floating gate 16 is coupled at a positive potential with respect to the grid electrode 14 and electrons are collected.

For an unselected memory cell, indicated at reference numeral 134, the unselected grid line 128-2 is biased at −1 V so that the potential between injector electrode 12 and the grid electrode 14 is too small for essentially any electrons to surmount the energy barrier between the grid electrode 14 and the retention insulator 20. The unselected injector line 130-2 is also biased at −1 V. As a result, for memory cells on unselected rows, but having a selected bit line, there is 2 V bias between the injector electrode 12 and the grid electrode 14. The word line bias for such a memory cell is such as to repel any electrons that are injected over the barrier between the grid electrode 14 and the retention insulator 20. Finally, the memory cells on unselected word and bit lines, 126 and 122, respectively, experience no bias between the injector electrode 12 and grid electrode 14.

An erase on the memory cells of the array 120 can be performed on either an entire row of memory cells or on a single memory cell. In row selective erase case, the grid lines 128 are all biased to about 6 V, the injector line 130 of the selected row biased at about ground, and the word line 126 of the selected row is biased at about −2V. On the unselected rows, the injector lines 130 are biased at about 6 V to prevent current between the injector lines 130 and the grid lines 130. If desired, the word lines 126 may also be biased to about 3 V to reduce the potential between the grid lines 130 and the floating gates 16 on the unselected word lines 126. It should be appreciated that the retention insulator 20 may be made thick enough to preclude significant leakage of charge between grid electrode 14 and floating gate 16 even with a potential of about 4 V to about 5 V between grid electrode 14 and floating gate 16 so that the word lines 126 on unselected rows may be grounded.

In the single cell select erase mode, the grid lines 128 and injector lines 130 of the unselected columns and rows are biased at about 4 V to lower the potential between the injector electrode 12 and grid electrode 14 below the level necessary to provide sufficient energy to the injected holes for surmounting the energy barrier between the fermi level in the grid electrode 14 and the valence band edge in the retention insulator 20.

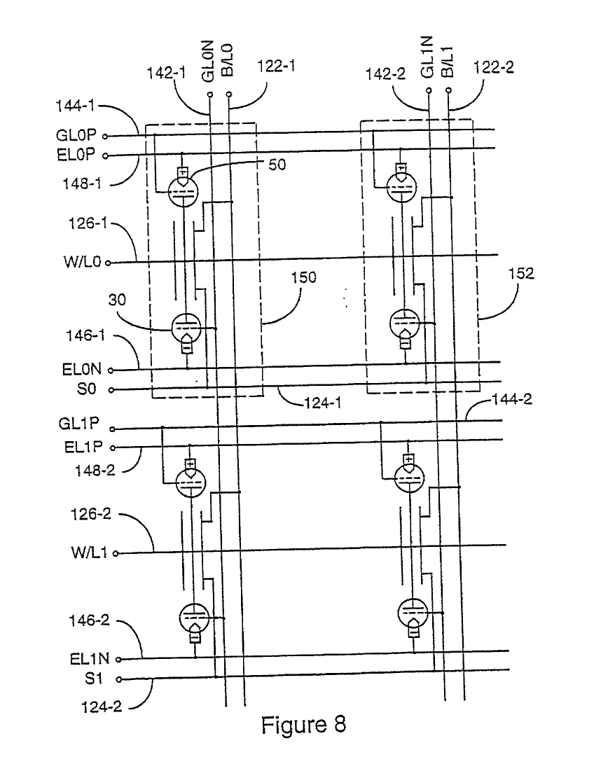

FIG. 8 illustrates a portion of a nonvolatile memory array 140 according to another embodiment of the present invention. Each memory element in the array 140 is a floating gate MOS transistor 100 coupled to a tunneling electron injector 30 and tunneling hole injector 50 as depicted in FIG. 6b. Although the floating gate MOS transistors 100 are n-channel, those of ordinary skill in the art will readily appreciate that they could also be p-channel. Each memory element is connected to a bit line 122, a source line 124, a word line 126, first and second grid lines 142 and 144, and electron and hole injector lines 146 and 148. In the portion of a nonvolatile memory array 140, four cells are arranged as two rows and two columns. There are two bit lines 122-1 and 122-2, two source lines 124-1 and 124-2, two word lines 126-1 and 126-2, two first grid lines 142-1 and 142-2, two se grid lines 144-1 and 144-2, two first injector lines 146-1 and 146-2, and two second injector lines 148-1 and 148-2.

In a specific embodiment, the word line 126 is separated from the floating gate of the floating gate MOS transistor 100 on the top and two sides in the word line direction by an ONO layer with an effective oxide thickness of about 20 nm, the tunneling electron injector 30 and tunneling hole injector 50 are formed on opposing faces of the floating gate with the grids separated from the floating gate with an oxide layer of about 20 nm thick. The gate oxide the floating gate MOS transistor 100 is about 6 nm thick, and the floating gate is 0.1 μm long, 0.1 μm wide, and 0.15 nm high. Accordingly, the floating gate MOS transistors 100 have a threshold voltage of about 0.4 to about 0.5 V.

In the erase mode of array 140, each of the memory cells is erased simultaneously by applying 5 V to the hole injector lines 148 and grounding all other lines in the array. Alternatively, the hole injector lines 148 may be biased at about 3 V, the word lines 126 biased at −3 V, and all of the other lines at about −1.8 V. With this set of biasing conditions, the maximum magnitude of any bias is reduced to 3 V. It should be appreciated by those of ordinary skill in the art that there are a variety of sets of other bias conditions that will erase the cells of the array 140.

To selectively program the cell in the array 140 indicated by reference numeral 150, 4 V is applied to word line 126-1, a bias of −2.5 V is applied to electron injector line 146-1, 1 V is applied to the first grid line 142-1, and 3 V is applied to the hole injector lines 148 and the two second grid lines 144-1 and 144-2. To inhibit electron injection to unselected cells, the unselected electron injector line 146-2 is biased at 0 V and a the unselected first grid line 142-2 is biased at −1 V. Under these conditions, the unselected cells have ±1 V applied between grid line 142-2 and electron injector line 146-2. These potentials are far too low to cause electron injection over the energy barrier between the grid electrode 34 and the retention oxide 40. The low biases applied between grid line 142-2 and electron injector line 146-2 permit only relatively small currents to flow between these lines in the unselected cells.

As has been discussed above, there are a great number of combinations of materials that can be used in forming the injection structures which lie within the scope of this invention. The fabrication of one particular embodiment is now described to illustrate how this invention can be implemented within an integrated circuit fabrication process using standard production techniques. In this particular embodiment, the MOS memory transistors are n-channel devices. It should be appreciated, however, that they could other wise be p-channel devices.

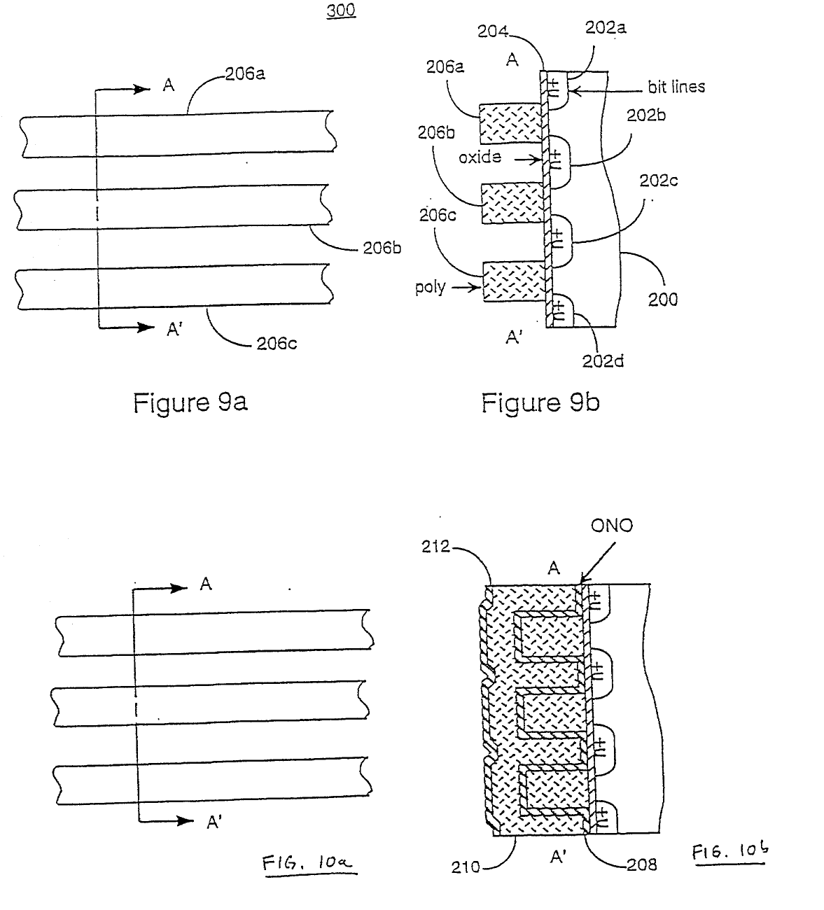

In FIGS. 9a and 9b, a silicon body 200 that is doped p-type uniformly in the direction extending along the surface of the wafer in the area of the array. A thin oxide 204 that forms the gate of the floating gate MOS memory transistor in disposed on the surface of the silicon body 200. Because oxide 204 is not exposed to high electric fields during operation, stress induced leakage current will not be generated and the gate oxide can be scaled toward the intrinsic limit of about 5 nm for retention. A layer of silicon is deposited on the oxide 204 and patterned with known means to form parallel traces 206. The silicon body 200 is implanted with an n-type dopant, preferably an n-type dopant with low rate of thermal diffusion such as As or Sb, to form doped regions 202 in the spaces between the silicon traces 206. The dopant may serve to dope the silicon traces 206, but the traces 206 serve to mask the regions under the traces 206.

In FIGS. 10a and 10b, after the implant is performed, an oxide/nitride/oxide, ONO, dielectric 208 is formed by one of several methods known in the art. It is preferred that the method employed does not expose the n-type implant 202 to high temperature treatment. A second layer of silicon 210 is deposited and doped either in situ or subsequent to deposition. A layer of silicon nitride is deposited on the second layer of silicon 210 and capped with a layer of deposited oxide to form the sandwich layer 212. The oxide layer in the sandwich layer 212 should be substantially thicker than the top layer of oxide in the ONO stack, preferably about 50 nm thick.

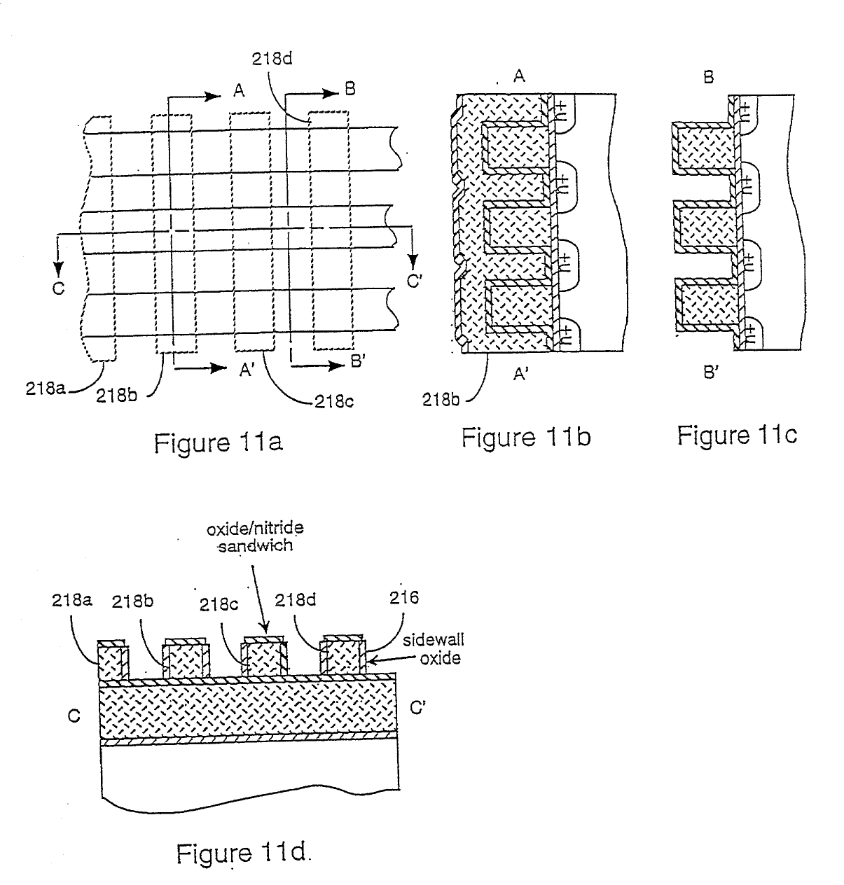

In FIGS. 11a through 11d, the sandwich layer 212 and underlying silicon layer 210 are then patterned into a series of parallel traces 218 that run perpendicular to the traces 206. A thin layer of silicon oxide 216, preferably about 20 nm thick, is grown on the side walls of the second layer silicon traces 218. The ONO dielectric prevents oxidation of the first layer silicon traces 206 or the underlying silicon body 200 during this process.

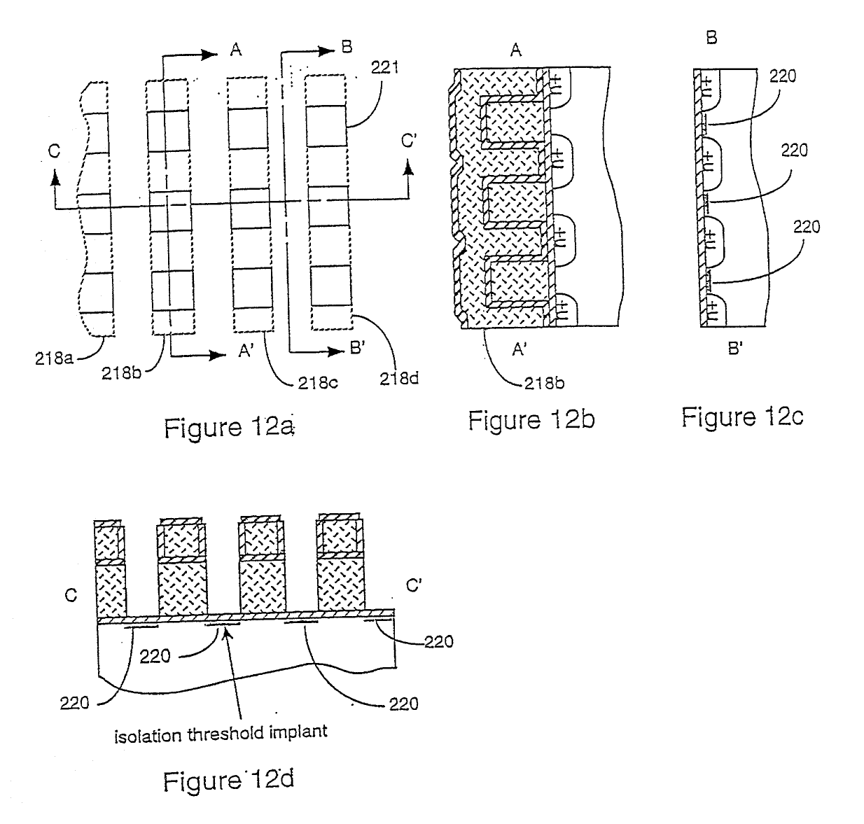

In FIGS. 12a through 12d, after the sidewall oxide 216 is grown on the second layer silicon traces, the ONO and underlying first layer silicon traces 206 exposed between the traces 218 of the second layer of silicon are etched away in an anisotropic etch. An implant of boron is made into the exposed regions 220 to raise the thresholds of these regions to provide isolation between the remaining portions of the first layer silicon traces 206 in the direction perpendicular to the second layer silicon traces 218. These remaining portions of the first layer silicon traces 206 form the floating gates of the floating gate memory transistors.

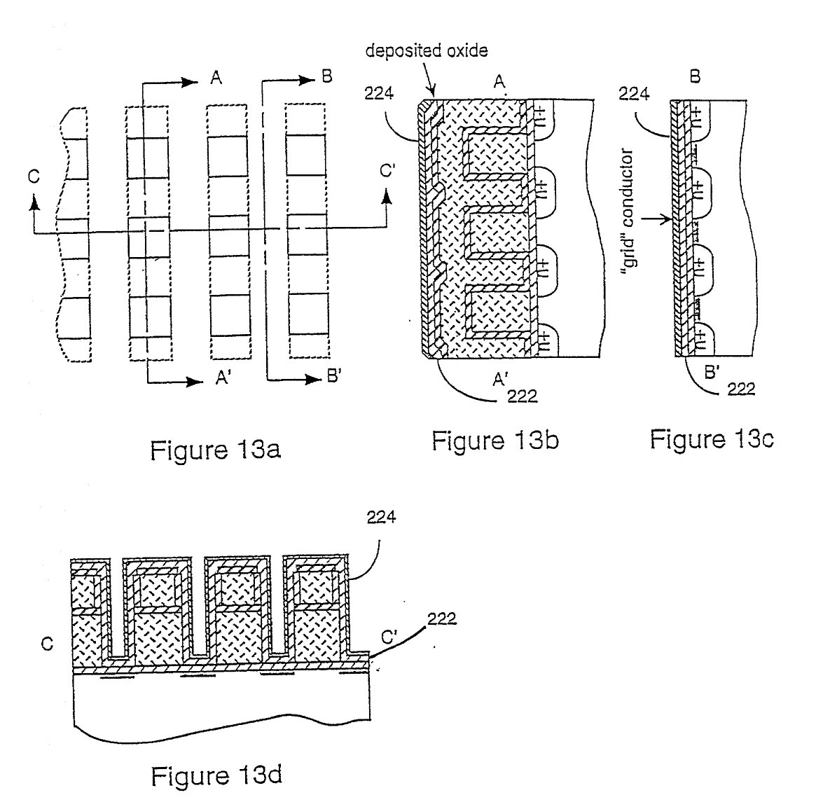

In FIGS. 13a through 13d, a layer of oxide 222 that forms a retention oxide is then deposited and annealed. A grid electrode 224 is deposited on oxide 222. As discussed previously, the grid electrode 224 may be any metal, alloy, or metallic compound that has the appropriate work function, conductivity, and range for “hot” carriers. The grid electrode 224 should be thin enough to allow a desired fraction of hot carriers to pass through without losing energy.

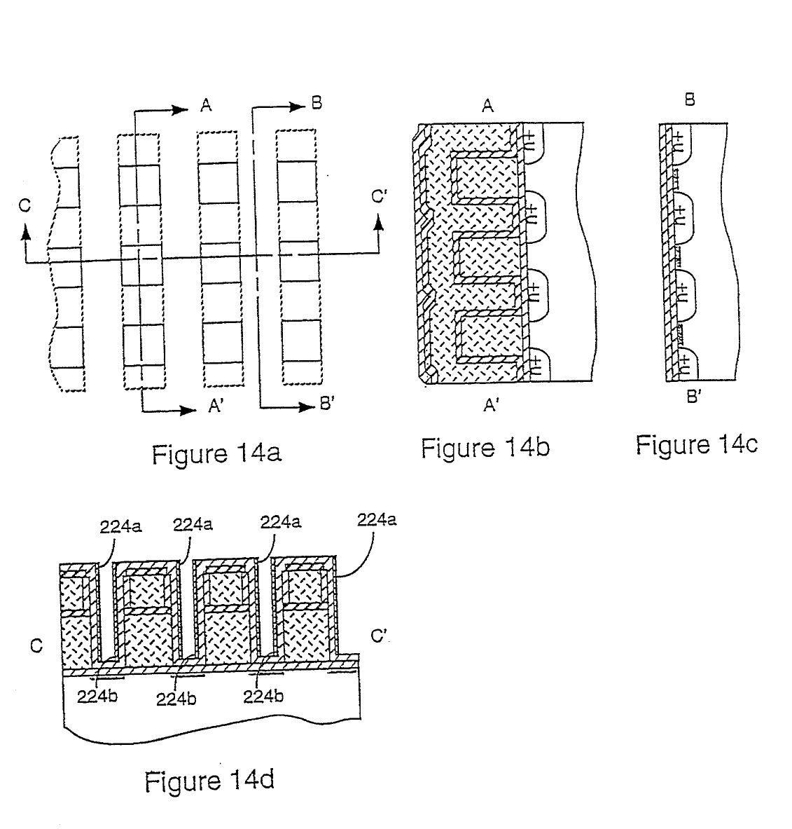

In FIGS. 14a through 14d, the grid electrode 224 is anisotropically etched to leave it only along the sidewalls of the first and second traces of the silicon layers 206 and 218 as is seen in FIG. 14.

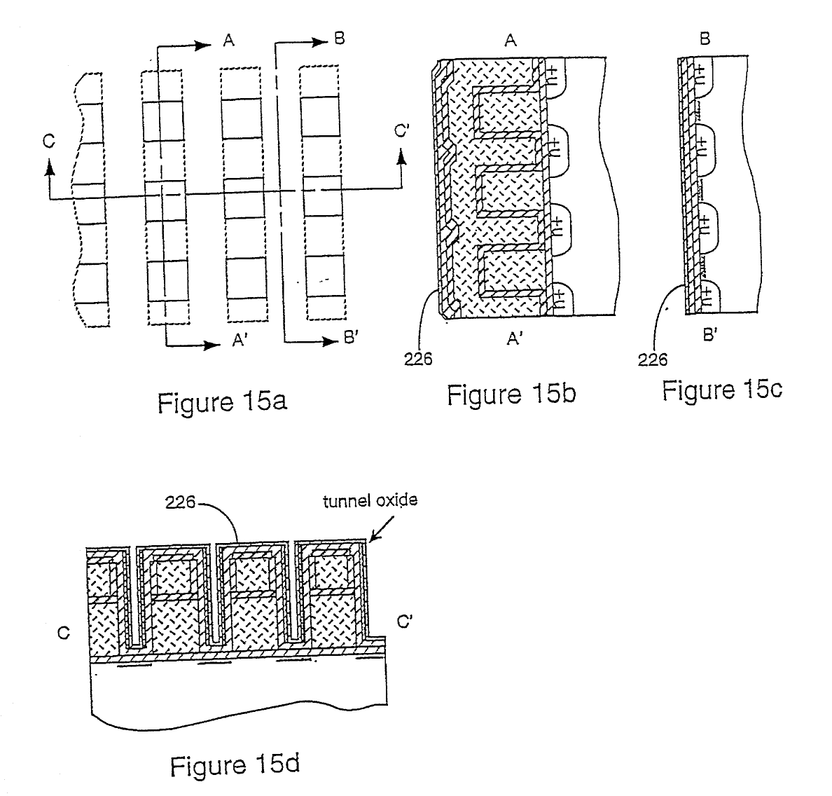

In FIGS. 15a through 15d, a tunnel layer silicon oxide 226 of about 5 nm is deposited so that it covers the grid electrode 224. Although silicon oxide is used in this embodiment, the tunnel insulating layer could be any one of or a combination of silicon nitride, silicon oxide, aluminum oxide, or other such insulator with a high dielectric strength that is compatible with integrated circuit processing technology.

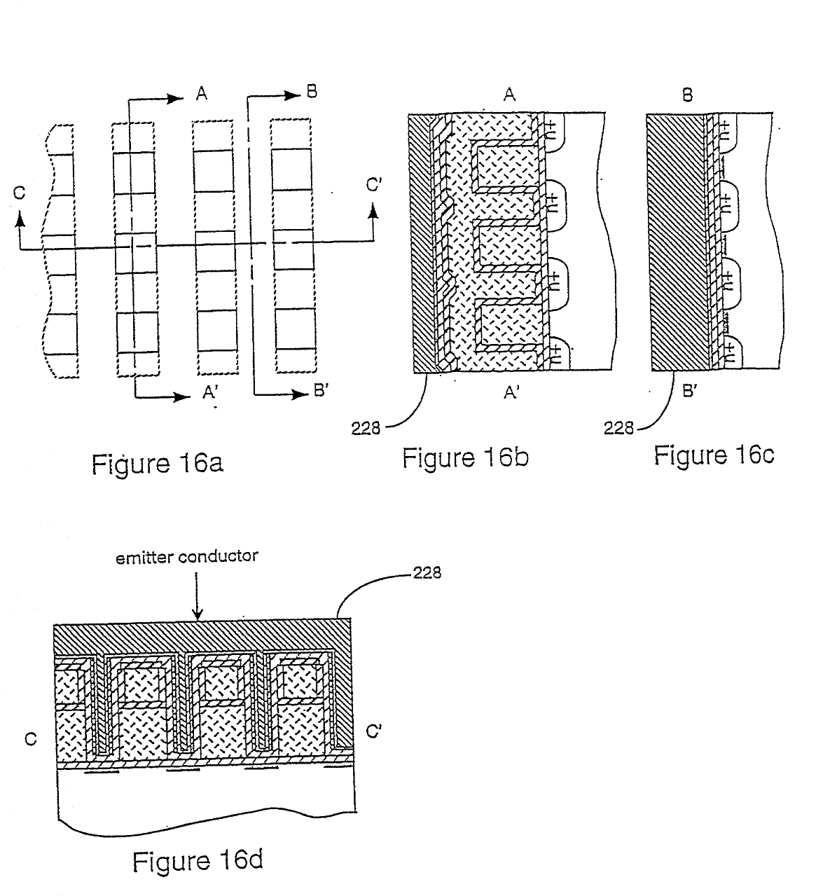

In FIGS. 16a through 16d, the injector electrode 228 is deposited by a method which will fill the space between the silicon traces and provide a reasonably smooth surface. The thickness of the injector electrode 228 should be more than 50% of the spacing between the silicon traces and preferably about 75% of this spacing. For example, if the spacing between the traces is 100 nm, the injector electrode thickness is preferably 75 nm.

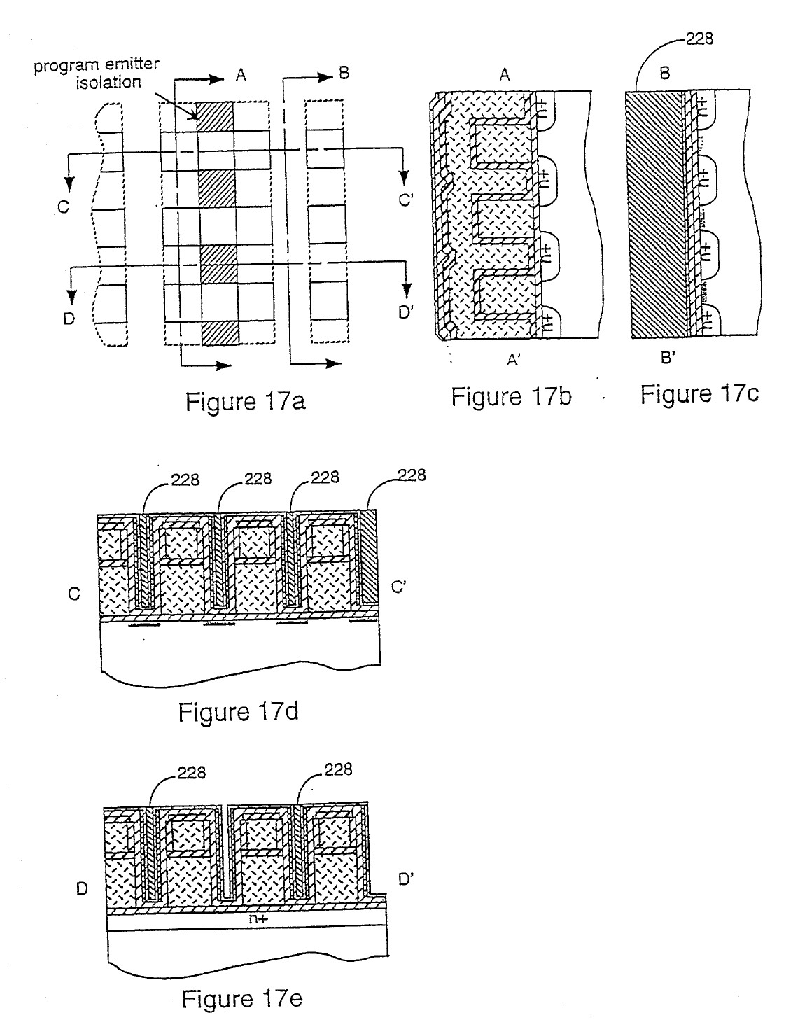

In FIGS. 17a through 17e, the material of the injector electrode 228 is then etched back to expose the tops of the traces so that the material of the injector electrode 228 lying in the channels between silicon traces is isolated from material of the injector electrode 228 lying in adjacent channels.

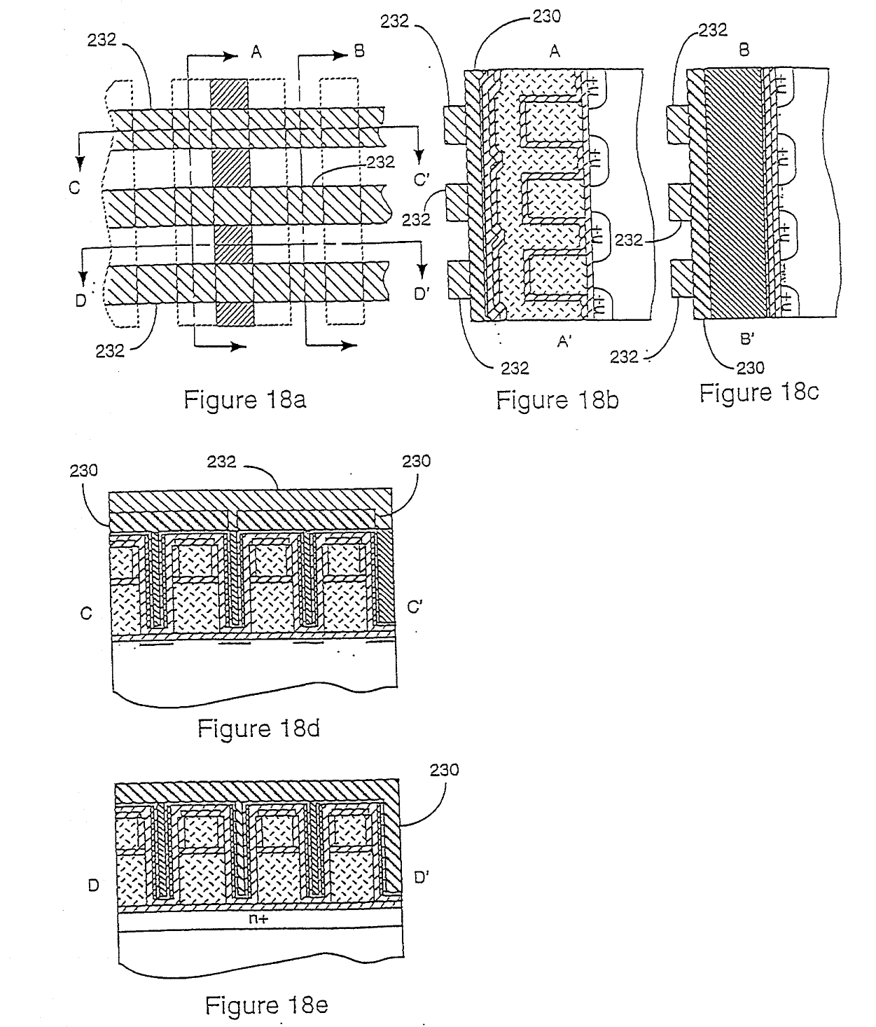

In FIGS. 18a through 18e, an isolating layer 230, of preferably either silicon nitride layer or a sandwich layer of a thin layer of silicon nitride under silicon oxide is deposited and selectively removed from the surface above every other channel. The channels that remain covered implement hole emitters. After the insulator 230 is selectively removed, a conducting layer 232 is deposited that is preferably a thin layer of titanium nitride covered with aluminum. The conducting layer 232 is selectively etched into traces with the aid of a photoresist mask. While the mask is in place, exposed material of the injector electrode 228 is etched from between the traces. The traces are placed so that the islands of material of the injector electrode 228 contacting the conducting traces 232 are adjacent to floating gates. These islands are the electron injectors.

In this structure, the second layer silicon traces 218 implement word lines, the diffused regions 202 implement source and drain regions of the floating gate MOS memory transistors. The hole emitters run along the word lines so that individual word lines, blocks of word lines or an entire array can be erased simultaneously, depending on the biasing of the grid lines, the injector lines, and the word lines. The duration required to erase a row should be on the order of μsec. Further, because the traces that set the injector biases for the electron injectors run perpendicular to those that set the bias for associated grids, the electron injectors can be individually addressed to permit the programming of individual cells.

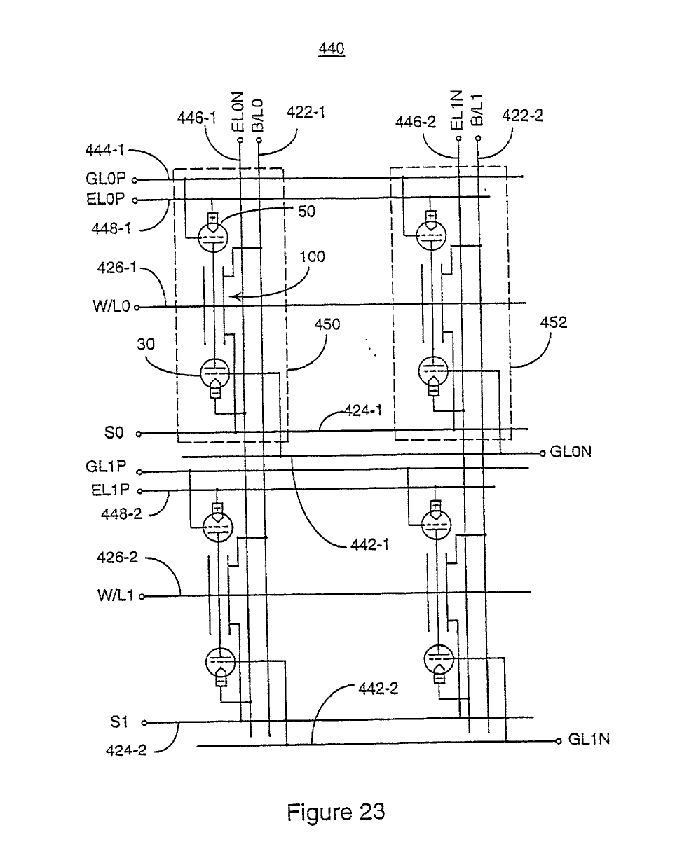

FIG. 23 illustrates schematically the electrical connectivity of the array just described. FIG. 23 shows a 2×2 portion 440 of an array fabricated as described above. In this embodiment the word lines 426-1 and 426-2 run parallel to the source lines 424-1 and 424-2. The bit lines 422-1 and 422-2 run through the array perpendicular to the word lines. The bit lines and source lines are connected to the drains and sources, respectively, of the memory transistors. The word lines connect to control gates that are capacitively coupled to the floating gate of the memory transistors. Each memory cell comprises a memory transistor 100, a hole injector 50 and an electron injector 30. Two cells 450 and 452 that are connected to word line 0 are shown surrounded by dashed lines in FIG. 23. In this embodiment, the grid lines 444-1, 444-2, 442-1, and 442-2 run parallel to the word lines, as do the injector lines 448-1 and 448-2 for the hole injectors. The injector lines for the electron injectors 446-1 and 446-2 are parallel to the bit lines and perpendicular to the word lines. Because the grid and injector lines for the electron injectors are perpendicular, a single cell that lies at the intersection of a set of grid and injector lines can be selected for programming. This allows unique data to be stored in the cells by clearing a row to a common charge state with the hole injectors that are in parallel along a row and then selectively programming the cells along the cleared row with the electron injector.

As will now be clear to those of ordinary skill in the art, the essential requirement for a selective operation is to have two sets of control lines running through the array perpendicular to each other. For the read operation, the bit lines and word lines perform the select function. For the write operation for the array shown in FIG. 23, the grid and injector lines for the electron injector perform this function. For the write operation for the array shown in FIG. 8, the grid and injector lines for the electron injector also perform the select function, but, in FIG. 8, the grid lines of the electron injector are parallel to the bit lines and the injector lines are parallel to the word lines. (To enable FIGS. 8 and 23 to be compared easily, the labels are the same for the same array elements, except that the label numbers in FIG. 8 begin with 1 and those in FIG. 23 begin with 4). The paths of the grid lines and the injector lines of the electron injectors in these two figures have been reversed, but the function remains the same. The choice between these two array connections can be made based on which is easier to implement. Similarly, although electron injection has been chosen as the selective operation in these two embodiments, it will be clear to those of ordinary skill in the art that the hole injectors could be wired for individual operation with the electron injection operation in parallel by row or column. What is important is that at least one of the write operations be cell selective.

The size of each cell is the minimum pitch in each direction so that the individual cell occupies an area of 4 l², wherein l is the minimum feature size. For example, in a technology having a minimum feature size of 0.1 μm, the cell size would be on the order of 0.01 μm² so that 10⁸ cells could be packed into a mm². Moreover, because the cells can be written with biases of about +3.5 V, the supporting circuitry can be made compatible with scaled technology.

An additional advantage of this technology is that the carriers that are injected over the retention barrier are fairly tightly bunched in energy. As a result, if the bias across the retention insulator is attractive, carriers will be collected with high efficiency. If the floating gate is charged so that the field across the retention insulator is repulsive, very few carriers will be collected. This permits control of the charging of the potential on the floating gate in bands of a few tenths of a volt so that storing multiple bits per cell is feasible.

As discussed above, silicon dioxide, SiO₂, is employed as the retention insulator in a specific embodiment, although it is also stated that silicon nitride could also be employed and may have advantage because it has a lower barrier height to the injection of both electrons and holes than SiO₂.

It is known that the scattering length for charge carriers in a conductor decreases very rapidly as the energy of the carriers increases above the fermi level in the conductor (See Krolikowski & Spicer, Phys. Rev., 185, pp. 882-900 (1969) and Krolikowski & Spicer, Phys. Rev., B1, pp. 478-87 (1970)). Since the scattering of carriers in the “grid” electrode is expected to be the limiting factor in the injection efficiency of embodiments of this invention, it would be very desirable to employ a material with low hole and electron barriers to the grid electrode.

Silicon nitride, Si₃N₄, has a barrier to electron injection that is approximately 1 eV lower than that of SiO₂ and a barrier to hole injection that is about 2 eV lower than that of SiO₂. These factors alone would make Si₃N₄ attractive for use as the retention insulator. However, there are at least two potential disadvantages to the use of Si₃N₄ in this role. The first is that concomitant with the lower barrier to injection of electrons or holes from the grid electrode is larger leakage of carriers between the floating gate and the grid electrode which results in much poorer retention of charge on the floating gate. A second disadvantage is that silicon nitride has traditionally had a high density of traps, probably as the result of a fairly high incorporation of hydrogen, that has resulted in the conduction of carriers through the dielectric being limited by Poole-Frenkel conduction rather the Fowler-Nordheim tunneling. The Poole-Frenkel conduction causes the leakage current to be much higher at low to moderate biases than if the conduction were Fowler-Nordheim limited.

The second disadvantage has been potentially obviated with the recent development of techniques of depositing silicon nitride with low enough defect densities that condition is essentially limited by Fowler-Nordheim tunneling (See Guo and Ma, “Tunneling Leakage Current in Oxynitride: Dependence on Oxygen/Nitrogen Content”, IEEE Electron Dev. Letters EDL-19, pp. 207-209 (1998)). However, the intrinsic Fowler-Nordheim tunneling current may still be too high to allow the retention required for some applications.

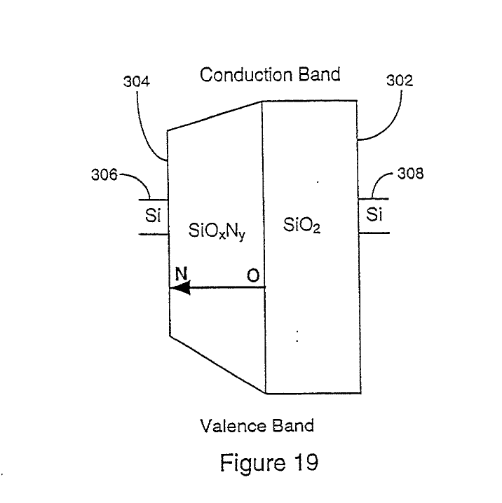

The retention problem can be overcome in accordance with an aspect of the present invention by combining a layer of very low leakage silicon dioxide adjacent to the floating gate with a layer of oxynitride which is in contact with the SiO₂ layer and adjacent to the grid electrode. The ratio of O and N in the oxynitride layer can be graded to provide a smooth transition from a nitrogen rich layer next to the grid electrode to almost stoichiometric silicon dioxide adjacent to the SiO₂ layer as is illustrated in FIG. 19.

FIG. 19 is a band diagram of a retention insulator structure composed of a layer 302 of SiO₂ and a layer 304 of SiOₓN_{y} in which the oxygen and nitrogen concentrations are graded so that the layer is essentially SiO₂ on its right side and Si₃N₄ on its left side. The floating gate 308 is assumed to be composed of silicon. The grid electrode 306 is also assumed to be composed of silicon. The energy barriers between the conduction bands and valence bands in the silicon of the grid electrode and these bands in the silicon oxynitride layer are significantly lower than those equivalent barriers between the SiO₂ and the silicon of the floating gate. This means that carriers can be more easily injected from the grid toward the floating gate than from the floating gate toward the grid which allows the structure to be separately optimized for retention of charge on the floating gate during storage mode and injection of charge onto the floating gate during writing mode.

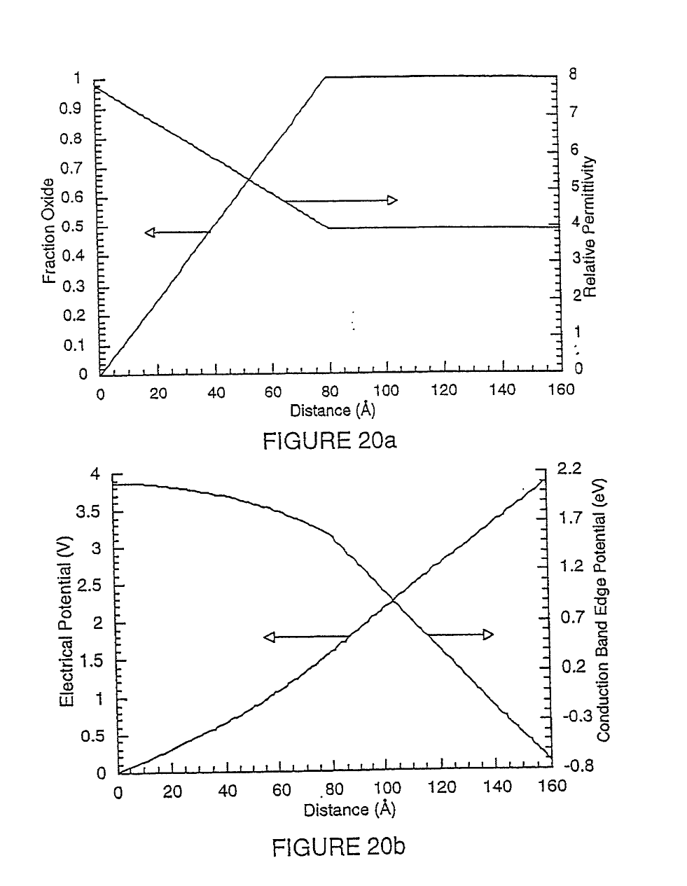

In addition to having a smaller band gap than SiO₂, Si₃N₄ has a higher electric permittivity. In the case of SiOₓN_{y}, the permittivity changes linearly with the change in composition. FIG. 20a is a plot of relative permittivity and fractional oxide content of a SiOₓN_{y} film deposited on a SiO₂ film for the case in which both films are 80 Å thick and the oxide fraction varies linearly from zero to one across the thickness of the SiOₓN_{y} film. As can be seen in the plot, the relative permittivity decreases from 7.8 to 3.9 linearly across the film.

The variation in permittivity across the SiOₓN_{y} film is important to the shape of the conduction band edge when an electric field is applied across the dual dielectric. The electric potential change, V, resulting from the applied field is given by

$$V = \int \vec{E} \cdot \vec{ⅆ l} = \int \frac{\vec{D}}{K {ϵ}_{o}} \cdot \vec{ⅆ l}$$

where K is the relative permittivity, εₒ is the permittivity of free space, and \vec{E}●\vec{dl} is the inner product of the electric field along the path of integration. The variation of the permittivity causes the electric potential to vary nonlinearly which effects the band edge potentials. FIG. 20b shows the variation of the electrical potential and the conduction band edge for the structure of FIG. 20a with an applied bias of about 3.8 V. The potential of the conduction band edge in the dielectric structure is plotted with respect to the conduction band edge of a silicon electrode in contact with the nitride edge of the SiOₓN_{y} film. The dielectric layer conduction band edge begins 2.1 eV above the silicon conduction edge and gradually declines in potential. This allows any electrons injected into the dielectric layer at the cathode to drift gradually across the SiOₓN_{y} film under the influence of the collecting field into the oxide film where they experience a stronger collecting potential.

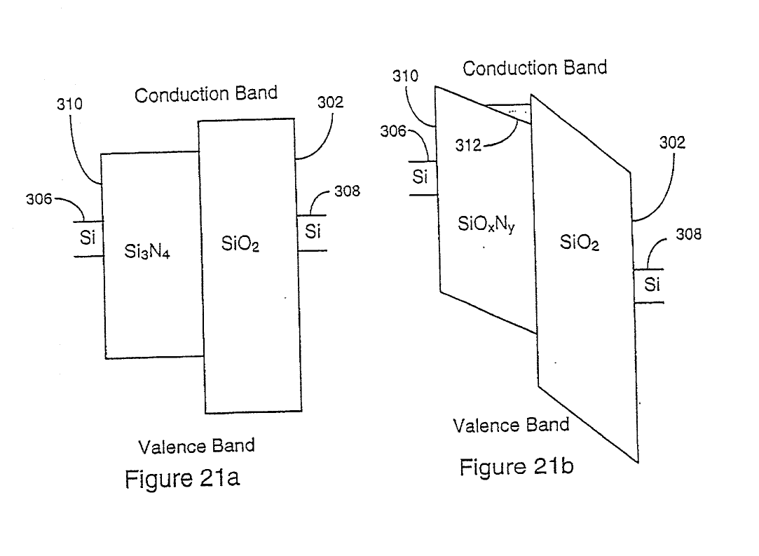

FIGS. 21a and 21b illustrate why the continuously collecting potential shown in FIG. 20b is important. In FIG. 21a, the graded SiOₓN_{y} film 306 from FIGS. 20a and 20b has been replaced with a simple film 310 of silicon nitride, Si₃N₄. The barrier to electron injection into this dual dielectric layer is 2.1 eV as was the case for the dielectric layer illustrated in FIGS. 19 and 20a, 20b.

However, when an electric field is applied across the structure, a potential well 312 is formed in which the injected electrons are collected rather than passing on to the anode. The electrons trapped in this well do not pass to the anode; moreover, they create a retarding electrical field that inhibits further electron injection into the dual dielectric layer. It is seen that it is important to grade the concentration of the SiOₓN_{y} film so that potential minimums are not created within the film when the structure is biased for carrier injection. (Although this discussion has focussed on electrons, it will be clear to those of ordinary skill in the art that similar considerations apply with respect to holes being injected into the valence band).

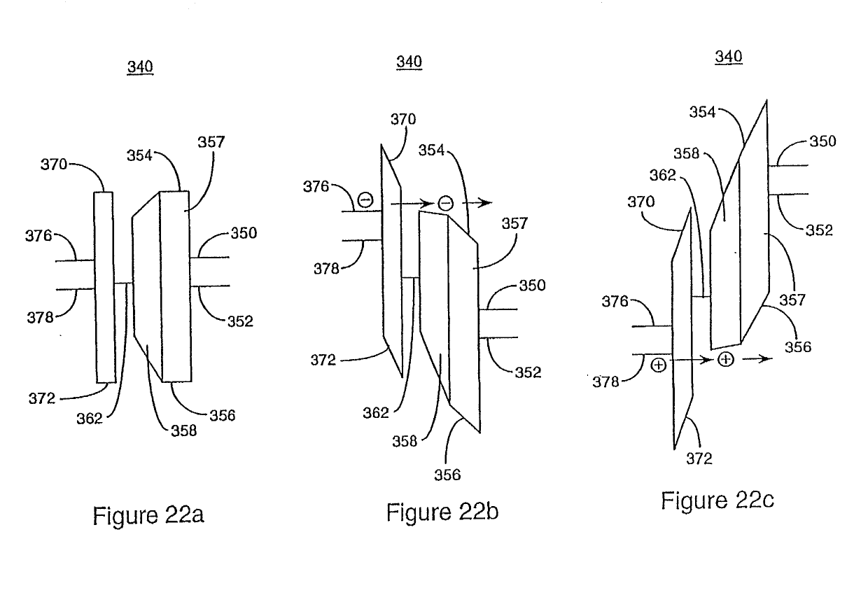

The application of a graded dielectric to charge injection structures is illustrated in FIGS. 22a-22c. A band diagram for a charge injection structure 340 with a dielectric having a graded band gap (as a result of graded composition) is shown in FIG. 22a with no bias applied. For this specific embodiment, the floating gate is chosen to be formed of silicon. The conduction band edge 350 and valence band edge 352 of the floating gate are seen on the right side of the structure. Adjacent to the floating gate is a dielectric composed of two films 357 and 358. A grid electrode is placed in contact with the dual layer dielectric. The fermi level 362 of this electrode is shown at reference number 362. The tunnel injector lies on the left of the structure. In this specific embodiment, this electrode is also chosen to be silicon. The conduction band edge 376 and the valence band edge 378 of the injector are shown on the left of the structure. The grid insulator is between the grid and tunnel injection electrodes. The grid insulator is SiO₂ in this specific embodiment. The conduction band edge 370 and valence band edge 372 of the grid insulator are shown.

The film 357 is chosen to have a wide band gap to prevent charge from leaking from the floating gate. In a specific embodiment this layer is chosen to be SiO₂ with a thickness in the range of 4 to 12 nm. A thickness of up to about 50 nm would also work. Lying between the blocking layer 357 and the grid is a dielectric film 358 that has a graded band gap. In this specific embodiment, this film is a SiOₓN_{y} film in which the oxide fraction is graded linearly from about unity at the interface with the film 357 to about 0 at the interface with the grid electrode. This film has a thickness in the range of 4 to 12 nm in this specific embodiment. The two films 357 and 358 form a composite dielectric film that serves as the retention insulator. The conduction band edge 354 and the valence band edge 356 of this insulator are shown in FIG. 22a.

When the injector electrode of this structure is biased 2 V to 2.5 V negatively with respect to the grid electrode and the floating gate is coupled 3.5 V to 4 V positive with respect to the grid electrode, the band edges become aligned as depicted in FIG. 22b. If the grid insulator is sufficiently thin, 2 nm to 6 nm in thickness in a specific embodiment, electrons will tunnel directly through the grid insulator and be injected into the conduction band of the grid electrode without loss of energy. Should the electrons reach the retention insulator interface without losing significant energy to scattering in the grid electrode, they can enter the conduction band of the retention insulator. The bias across the collection insulator is chosen so that any electrons injected experience a potential gradient that will drift them toward the floating gate. It is known that the electron-electron scattering distance increases exponentially with decrease in the energy of an electron above the fermi level. A decrease in energy from 4 to 3 eV above the fermi level in the grid electrode can result in more than doubling the mean-free-path. The result is a very substantial increase, as much as 10×, in the fraction of the injected electrons that reach the retention insulator without significant energy loss.

As FIG. 22a illustrates, the same principles can be applied to hole injection with the differences being that the decrease in required hole energy is about 2 eV because the barrier to hole injection for Si₃N₄ is about 2 eV less than that of SiO2.

Although the band edges 354 and 356 are shown in FIGS. 22b and 22c to have linear potential variation with distance, it should be clear from the discussion of FIG. 22b that their behavior is curvilinear; however linear behavior is easier to draw and illustrates the essential behavior.

Although the two films shown in this specific embodiment are of the same thickness, this is not necessary according to the teachings of this invention. The blocking layer, film 357 in FIGS. 22a-22c, must only be thick enough to prevent charge from leaking from the floating gate at a rate that degrades the retention of the charge, and hence stored data, under normal storage conditions. The graded dielectric film in contact with the grid electrode need only be thick enough to allow the smooth transition between smaller and larger band gap regions.

Dividing the retention layer into two films is somewhat arbitrary. It is within the teaching of this invention for the retention insulator to be a single film deposited in a single operation in which the portion near the floating gate is composed of wide band gap dielectric material which gradually grades into narrow band gap dielectric material. For example, the retention insulator could be formed by depositing a film that is composed of principally SiO₂ for the 70 Å nearest the floating gate electrode and that then grades gradually to Si₃N₄ at the grid electrode interface.

Other materials can be substituted for SiO₂ and SiOₓN_{y} as long as there is a dielectric near the floating gate that inhibits the leakage of charge from the floating gate and a dielectric material that grades gradually from the wide band gap of the blocking layer to a narrower band gap where the retention insulator contacts the grid electrode.

Those of ordinary skill in the art having the benefit of this disclosure will now realize that many changes and modifications may be made without departing from this invention in its broader aspects, and, therefore, the appended claims are to encompass within their scope all such changes and modifications as fall within the spirit and scope of this invention.

As was pointed out in the discussion regarding FIG. 5b above, there is the possibility for electrons to tunnel from the grid electrode to the floating gate under the bias conditions that cause holes to tunnel from injector. This limits the efficiency of the hole injection process because the electrons tunneling from the grid are a parasitic current that does not help to make the net charge on the floating gate more positive. As is pointed out above, this parasitic current can be reduced by employing a grid material with a larger work function. The elements with the highest work functions are platinum (Pt) and iridium (Ir) which have work functions of about 5.3 eV (See S. M. Sze, “Physics of Semiconductor Devices”, John Wiley and Sons, Inc. New York, p. 366 (1969)).

It is, however, very desirable that the materials used in the fabrication of those memory cells be those commonly employed in the fabrication of integrated circuits because the equipment and processes for deposition and etching of layers of these materials are well developed. Pt and Ir are noble metals that are both inert under most conditions and have very high melting temperatures. These materials can be deposited by sputtering and removed by ion milling. Unfortunately, the sputtering deposition process results in layer thicknesses that vary considerably depending on the angle of the receiving surface to the source and ion milling is not very selective.

Notably, p+ silicon has a work function of about 5.2 eV, which is nearly as large as those of Pt and Ir, and techniques for chemical vapor deposition and plasma etching of silicon are very well developed in the integrated circuit art. These properties make p+ silicon seem like a good choice for the grid electrode material for hole injection.

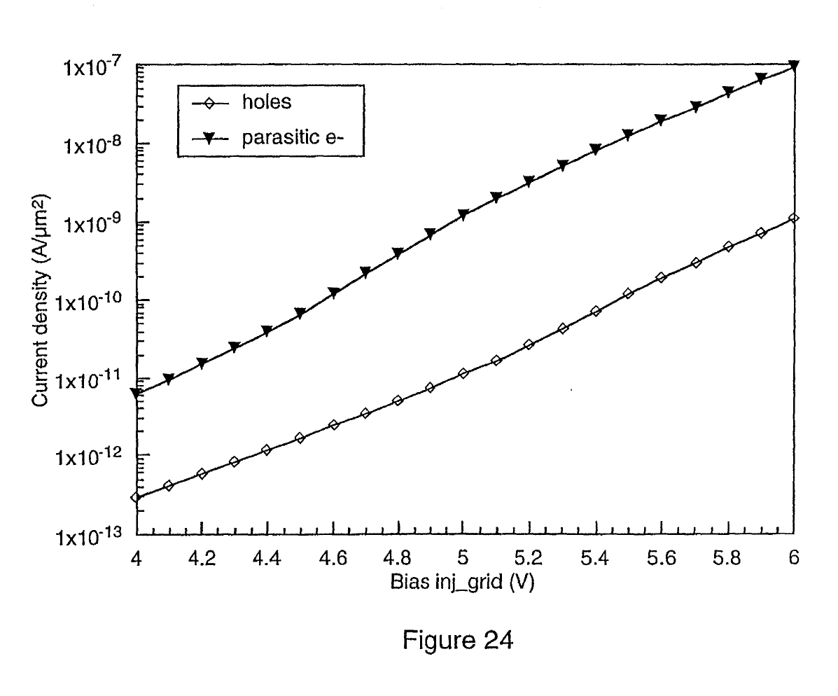

Unfortunately, when the electron and hole currents are calculated for a memory cell in accordance with the teachings of this invention for the case of bias to favor hole injection from a p+ Si (silicon) injector with a p+ Si grid electrode, the electron currents are found to be one to two orders of magnitude larger than the hole currents as shown in FIG. 24.

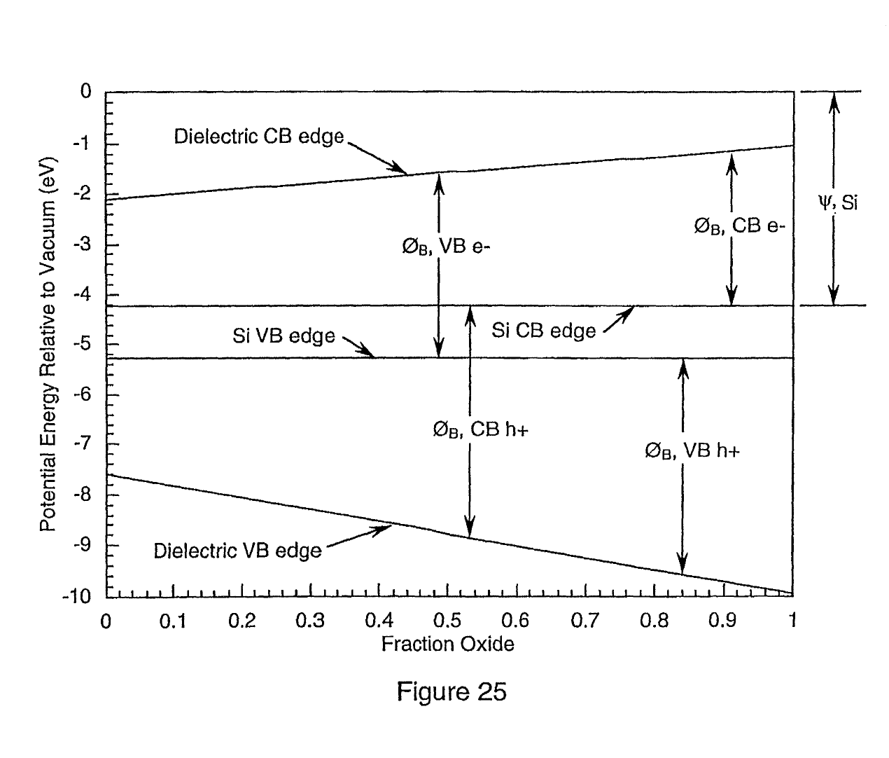

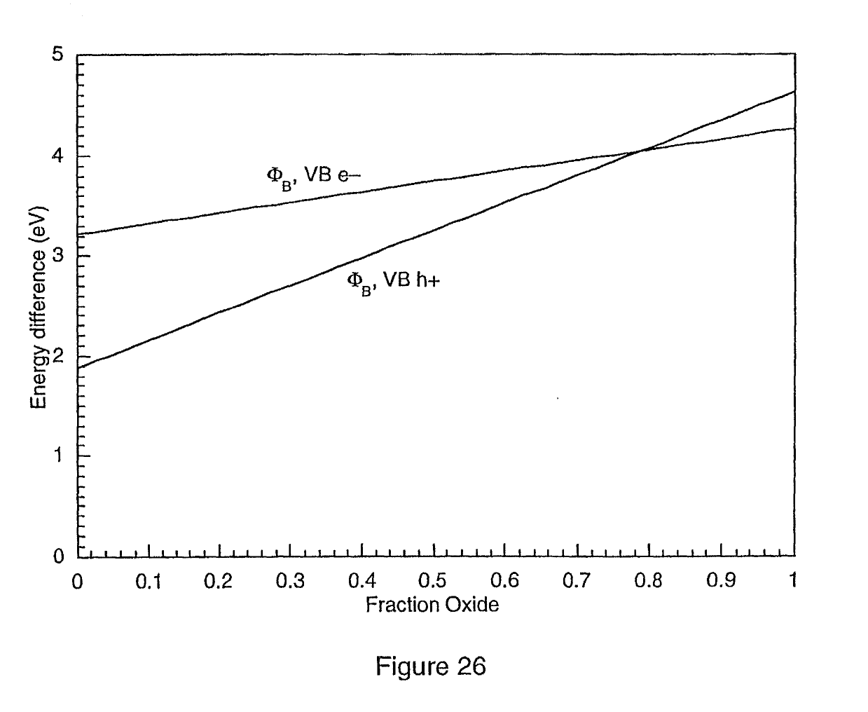

However, by appropriate choice of the dielectric material (grid insulator) disposed between the injector and the grid (grid insulator), this effect can be avoided. FIG. 25 shows the variation of the band edges in the SiOₓN_{y} system as a function of the relative oxide concentration. As is apparent, the valence band edge decreases in energy relative to the vacuum level faster than the conduction band edge increases in energy as the oxygen content of the material increases. This is important because the electron tunneling probability for p+ doped Si is exponentially dependent upon the Si valence band edge to dielectric valence band difference while the hole tunneling probability is exponentially dependent on the Si valence band to dielectric valence band energy difference. FIG. 26 is a plot showing the differences of the Si valence band to dielectric conduction band difference, which is important to electron tunneling, and the Si valence band edge to dielectric conduction band energy difference, which is important to hole tunneling. It is seen in FIG. 26 that the tunneling energy barrier for holes becomes less than that for electrons from the valence band when the oxide fraction is less than about 77%.

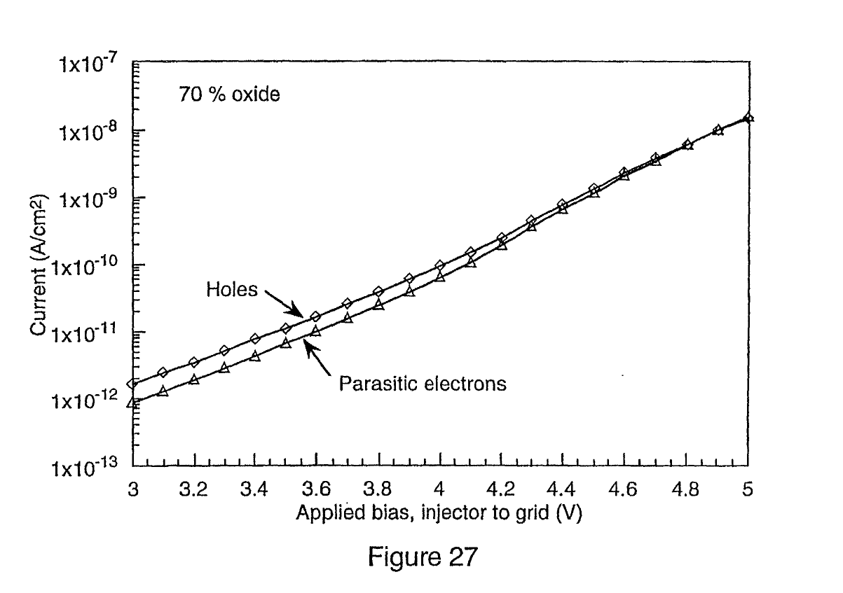

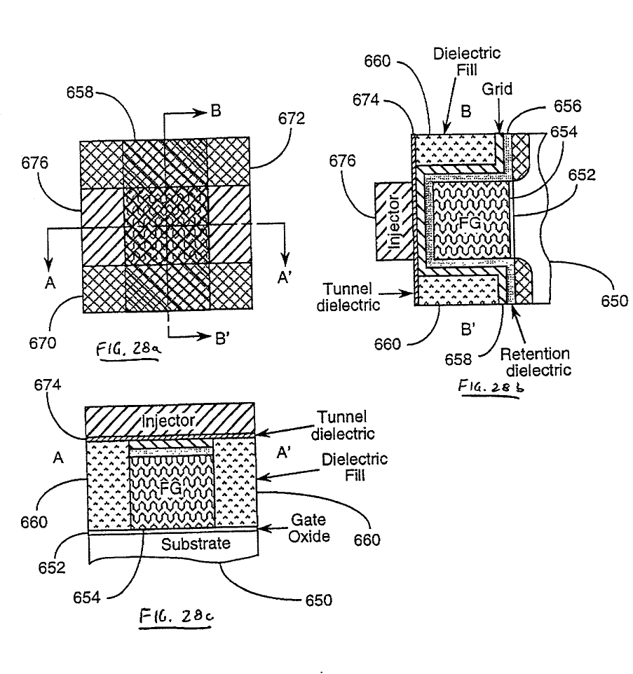

The consequence of the variation of barrier heights with material parameter is shown in FIG. 27 which compares the calculated value of the hole current to that of the parasitic electron current for a dielectric having 70% oxide. In the lower bias voltage range in which the cell is preferentially operated, the hole current is at least 50% greater than the electron current.

It will now be clear to those of ordinary skill in the art that other ratios of oxide to nitride in the compound dielectric will also produce this desired result. Additionally, the oxide compounds BeO, MgO, ZrO₂,CGaO, SrO, Y₂O₃, Pr₂O₃, ThO₂, ZrO₂, and Al₂O₃ have been shown either experimentally, theoretically, or both to be stable in contact with Si. (See K. J. Hubbard and D. G. Schlom, “Thermodynamic Stability of Binary Oxides in Contact with Silicon”, J. Mater. Res., 11, pp. 2757-76 (1996) and are therefore also suitable.

It should now be clear to those of ordinary skill in the art that those of these compounds, or tertiary mixtures of these compounds, in which the barrier to electrons tunneling from the valence band of the emitter through the dielectric is greater than or approximately equal to that of holes tunneling from the valence and of the emitter through the dielectric are also suitable for use as an insulator between the hole injector and the grid in accordance with this aspect of the invention.

It should also now be clear that parasitic electron tunneling during erase with hole tunneling can exist and can reduce the erase efficiency with grid materials other than silicon. It should also be clear to those of ordinary skill in the art that the teachings of this disclosure can be applied to modify the dielectric through which the hole tunneling occurs so as to improve the erase efficiency in these cases as well.

Previous embodiments of this invention described in detail above have employed both a control gate and a grid line in the array. The control gate has been used as the principle control of the floating gate potential and the grid electrode has been used in combination with the injection electrode to control the flow of carriers from the injector through the grid to the floating gate. The fabrication of products incorporating this invention can be simplified by combining the electrodes that provide the control gate and grid functions. This combination may be effected as now described.

FIG. 28a is a layout view of a floating gate memory cell in accordance with this embodiment of the invention. FIG. 28b is a cross-sectional view take along line B-B′ of FIG. 28a. FIG. 28c is a cross-sectional view taken along line A-A′ of FIG. 28a. In the embodiment illustrated in FIGS. 28a, 28b and 28c, a pair of traces 672 and 674 of a second type, e.g., n-type, are formed in a portion of a semiconducting substrate 670 of a first type, e.g., p-type. A stripe of dielectric 652, typically SiO₂, lies in the form of a stripe atop this substrate. An isolated conductor 654 lies atop the dielectric between the two doped traces 672 and 674 and forms the floating gate. Successive layers of a retention dielectric 656 and a grid conductor lie in a strip that is aligned with the floating gate and perpendicular to the doped traces. A dielectric fill material 660 surrounds the floating gate. The top of the dielectric fill is coincident with the top surface of the grid conductor where it lies on top of the floating gate. A tunnel dielectric layer 674 lies on top of the grid conductor where it lies atop the floating gate. An injector conductor 676 runs in a strip that crosses the top of the floating gate a runs parallel to the doped traces in the substrate. The tunnel injector is shown here as covering the whole of the top surface of the cell, but it should now be clear to those of ordinary skill in the integrated circuit art that it is only necessary for this layer to lie between the injector and the grid.

A floating gate transistor is formed wherein the floating gate lies above the substrate. The two doped traces in the substrate act as the source and drain of this transistor. The channel of the transistor is formed under the floating gate in the region between the source and drain.

TABLE I
Bias Voltages for Various Operations

| | OPERATIONS: | | |
|---|---|---|---|
| BIAS: | ERASE | PROGRAM | READ |
| DRAIN | −4.0 V | +2.0 V | +1.0 V |
| SOURCE | −4.0 V | +2.0 V | +0.0 V |
| BODY | −4.0 V | +0.0 V | +0.0 V |
| GRID | −2.5 V | +2.0 V | +1.5 V |
| INJECTOR | +2.5 V | −2.0 V | +0.0 V |

The operation of this cell can be explained with the help of Table I. Consider first the erase operation. In a typical flash memory, erase is a block operation that is applied to a block of cells simultaneously. In this discussion, it will be assumed that the cell is part of a block that is within a p-well, the bias of which can be varied within an n-well or n substrate. Assume that the cell under consideration is charge neutral and is to be erased. Assume also that a cell with a neutral floating gate has a threshold that is at 1.0 V with respect to the floating gate potential. Finally, assume that the capacitive coupling between the grid and the floating gate is the same as that between the floating gate and substrate region and that the capacitive coupling of the injector to the floating gate can be neglected.

With the assumption made about the capacitances, application of a bias of −2.5 V to the grid electrode will couple a potential of −1.25 to the floating gate. Application of biases of −4 V to the transistor body, drain and source will couple another −2.0 V to the floating gate for a total potential on the floating gate of −3.25 V. With a total potential difference of 5 V between grid and injector, holes will be injected into the floating gate with an energy of 5 eV. This is enough to surmount a barrier of 5 eV between grid and retention dielectric. For example, the barrier between the top of the valence band in silicon and the top of the valence band in SiO₂ is 4.5 eV. Holes that reach the surface of the retention dielectric without losing too much energy will drift across the dielectric and be collected on the floating gate initially because there is a potential difference of 0.75 V across this dielectric that is directed to collect holes. As the holes are collected, the floating gate potential changes until the potential difference across the retention dielectric is zero. The collected charge at this time has increased the floating gate potential by about 0.75 V. Further injection of holes across the retention dielectric face a repelling field so the collection of holes is self limiting.

When the biases are removed, the now-erased gate has a potential of 0.75 V. If the read conditions are now applied, the grid electrode will couple 0.75 V onto the floating gate for a total potential of 1.5 V. Since the threshold is 1.0 V, the n-channel floating gate transistor will conduct and current will flow between source and drain. This cell is sensed as erased.

To program an erased cell, assume that the grid is first biased at 2 V. This will capacitively couple 1 V onto the floating gate so the gate potential is increased to 1.75 V which will establish an inversion region between source and drain. When the source and drain potentials are increased to 2 V, another 1 V is coupled onto the floating gate for a total potential of 2.75 V. Thus the floating gate is 0.75 V positive with respect to the grid. Electrons that are injected into the grid as a result of the 4 V potential between grid and injector are collected onto the floating gate if they reach the retention dielectric with sufficient energy to surmount the barrier. Collection continues until the potential of the floating gate is reduced to that of the grid electrode, i.e. 2.0 V. When the biases are removed, the floating gate is charge neutral. If read biases are applied, the floating gate is coupled to a potential of 0.75 eV. Since this is less than the threshold, little current flows between source and drain and the floating gate is sensed as programmed.

It will now be clear to those of ordinary skill in the integrated circuit art that other combinations of biases and threshold voltages would lead to similar operation that is within the teaching of this invention.

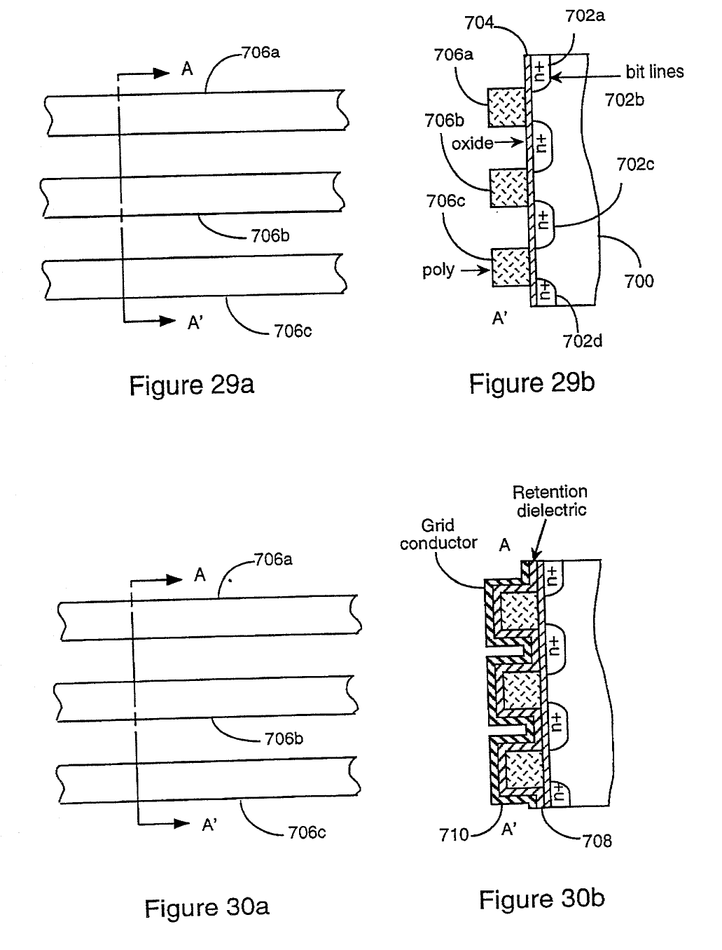

A means of fabricating the embodiment illustrated in FIGS. 28a, 28b and 28c can be described with the aid of FIGS. 29a, 29b, 30a, 30b, 31a, 31b, 31c, 32a, 32b and 32c. After formation of the isolation for the circuits peripheral to the array, the wells are implanted. A gate dielectric layer is formed over the surface of what will be the memory array. Dielectric layers of possibly other thicknesses may also be formed on other parts of the wafer. In the remainder of this description, the operations on other parts of the wafer to form the peripheral circuitry are omitted, but it should be clear to those of ordinary skill in the integrated circuit art how to perform these operations in conjunction with the operations that are described for the formation of the memory array.

After the floating gate dielectric is formed a polysilicon layer is deposited. The polysilicon layer is coated with a layer of photoresist which is selectively exposed to ultraviolet light and then developed to form stripes of photoresist where the polysilicon should remain. The polysilicon is etched away where it is not masked by the photoresist using plasma etching techniques well known to those of ordinary skill in the art. After the photo resist pattern is removed the stripe 706 remains on the surface of the floating gate dielectric. This is the first nonvolatile (NV) masking operation.

After this operation, photoresist is applied and patterned again. This mask exposes the memory array region. An ionized n-type dopant is implanted into the substrate not covered by the poly with an ion implanter as is well known to those of ordinary skill in the art. The implant forms the n+regions 702 seen in FIG. 29b which represents the wafer after the resist is removed. This is the second NV masking operation. In some cases, the n-type implant may also be used to form the source and drain regions of n-channel transistors in the peripheral regions. If this is possible a masking operation can be saved.

After proper cleaning, the retention dielectric and grid conductor are deposited. For reasons that will become clear later, a “hard mask” material such as silicon nitride is deposited over the grid conductor. The retention dielectric and grid conductor are shown in FIGS. 30a and 30b. The “hard mask” layer is omitted from the figures for reasons of clarity. A layer of photoresist is applied and patterned to expose the regions in which the grid conductor should be removed. The regions 712 in which the stripes of grid electrode material should remain are covered with the resist, as are regions where “tabs” of grid electrode material are desired so that electrical contact can be made to the grid electrodes. During the etching of the regions defined by this mask, the grid conductor, the retention dielectric and the floating gate polysilicon are successively etched. The last step separates the poly stripes defined with the first NV masking operation into isolated polysilicon floating gates. This is the third NV masking operation.

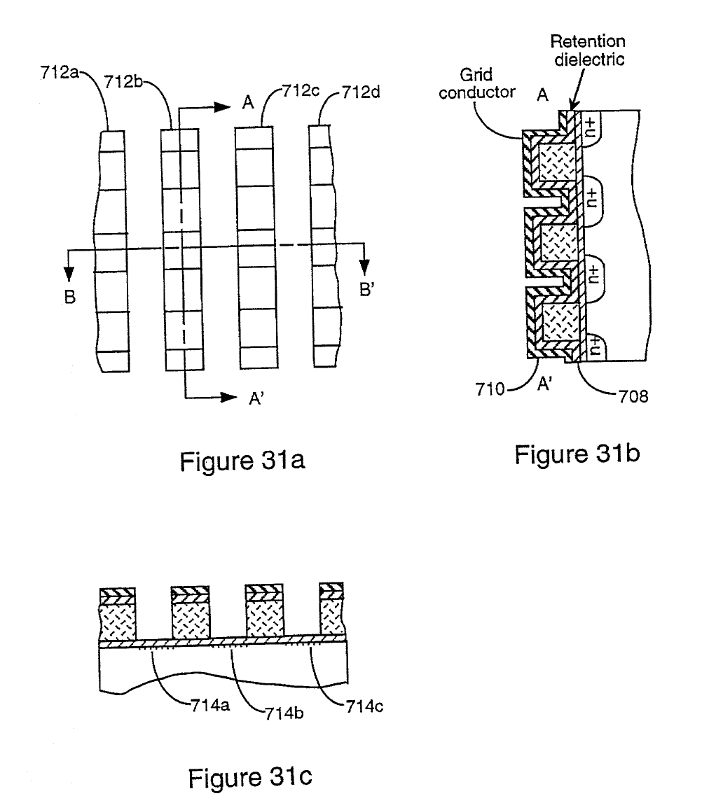

After the photoresist is removed and the wafer properly cleaned a layer of dielectric is deposited that is thick enough to fill in all of the gaps between the features remaining after the etch of the grid lines. This dielectric fill 718 is polished back using chemical mechanical polishing (CMP)until there is a planar surface that is level with the top of the grid layer where it lies on top of the floating gates. The CMP process actually stops on the hard mask layer that was earlier deposited atop the grid material. This protects the grid conductor from erosion in the CMP. The hard mask is then selectively removed which results in the structure shown in FIGS. 31a, 31b and 31c.

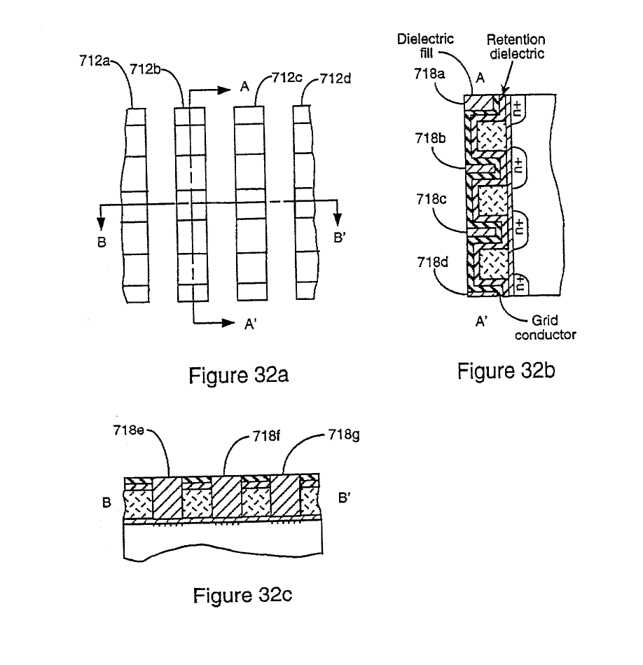

The tunnel dielectric 720 and the injector conducting layer are then deposited on the planarized layer. Finally, the injector stripes 722 are defined in the injector conducting layer by photomasking and etching using standard methods. Areas for contacting the injector stripes are also defined at the same time. This is the fourth NV masking operation. The structure that results after the resist is removed is shown in FIGS. 32a, 32b and 32c.

After the structure shown in FIGS. 32a, 32b and 32c is formed, the wafer is completed by deposited further layers of dielectrics and metals with appropriate masking, etching and CMP operations interspersed to form the wiring for the circuit as is well known to those of ordinary skill in the integrated circuit art.

The transistors required for the peripheral circuitry can be formed with well-known methods in steps prior to or interspersed with the steps described above for the formation of the memory array. As mentioned before the transistor gate dielectrics would probably be formed prior to the deposition of the floating gate conductor. Although described here as polysilicon, those of ordinary skill in the art will now appreciate that there are alternative conductors that could be used for the floating gate conductor including refractory metal silicides, refractory metal nitrides, refractory metals and other known charge storage materials.

In some cases, it may be desirable to use the same material for the floating gate conductor and for the gate conductor of the peripheral transistors. In this case the masking operation used to form the stripes of floating gate material, the first NV masking operation, could also be used to define the gates of the peripheral transistors.

Similarly, it may be possible to use the implant that is employed to form the source and drain traces in the array to form the sources and drains of the peripheral n-channel transistors. Other possibilities for combining operations for formation of the array structures and the peripheral transistors may arise and are included within the scope of this invention.

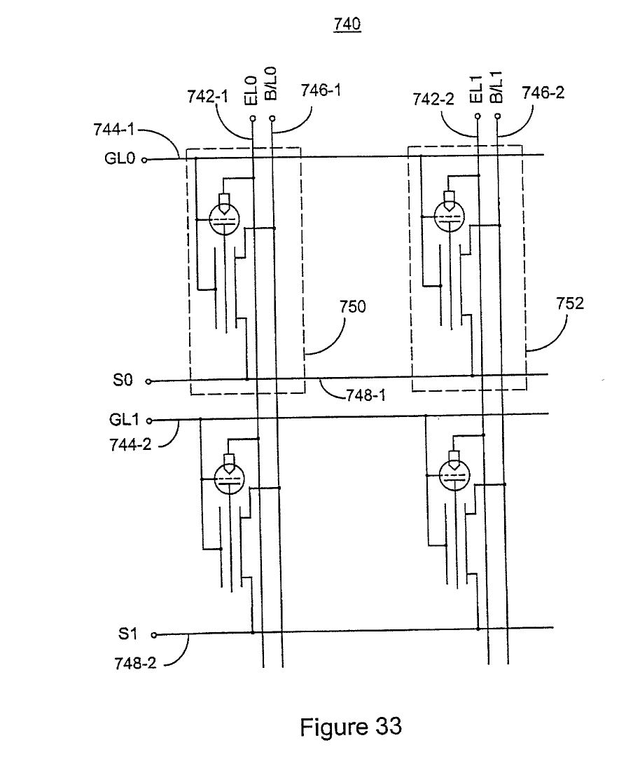

The cell shown as a physical embodiment in FIGS. 28a, 28b and 28c is shown embedded in a two by two array in FIG. 33. If this figure is compared with FIG. 7, it is seen that the combination of the grid and word lines has resulted in the reduction of the number of control lines in the array by one per row.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims.

What is claimed is:

1. A nonvolatile memory cell comprising:
a floating gate MOS transistor including:
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body;
a floating gate dielectric disposed between said floating gate and said semiconductor body; and
a tunneling hole injector including:
a conducting injector electrode from which holes are emitted;
a grid insulator disposed adjacent to said conducting injector electrode;
a grid electrode disposed adjacent to said grid insulator; and
a retention insulator disposed adjacent to said grid electrode,
wherein said grid insulator comprises an oxygen-containing material.

2. A nonvolatile memory cell in accordance with claim 1, wherein said oxygen-containing material comprises SiOₓN_{y} with an oxide fraction of less than about 77%.

3. A nonvolatile memory cell in accordance with claim 1, wherein said conducting injection electrode comprises p+ doped silicon and said grid electrode comprises p+ doped silicon.

4. A nonvolatile memory cell in accordance with claim 3, wherein said oxygen-containing material comprises SiOₓN_{y} with an oxide fraction of less than about 77%.

5. A nonvolatile memory cell in accordance with claim 3, wherein said oxygen-containing material comprises a metal oxide.

6. A nonvolatile memory cell in accordance with claim 3, wherein said oxygen-containing material comprises one or more compounds selected from the group consisting of: BeO, MgO, ZrO₂, CaO, SrO, Y₂O₃, Pr₂O₃, ThO₂, ZrO₂ and Al₂O₃.

7. A nonvolatile memory cell in accordance with claim 1, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate.

8. A nonvolatile memory cell in accordance with claim 2, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate.

9. A nonvolatile memory cell in accordance with claim 3, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate.

10. A nonvolatile memory cell in accordance with claim 4, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate.

11. A nonvolatile memory cell in accordance with claim 5, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate.

12. A nonvolatile memory cell in accordance with claim 6, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate.

13. A nonvolatile memory cell as in claim 1, wherein said floating gate comprises polysilicon.

14. A nonvolatile memory cell in accordance with claim 1, wherein said retention insulator is formed of a layer of silicon oxide having a thickness in a range of about 8 nm to about 50 nm.

15. A nonvolatile memory cell in accordance with claim 1, wherein said grid electrode is thin enough to minimize loss of energy of injected charge carriers and thick enough to conduct away charge carriers that lose energy and are thermalized in said grid electrode.

16. A nonvolatile memory cell in accordance with claim 1, wherein said grid electrode has a thickness in a range of about 10 nm to about 50 nm.

17. A nonvolatile memory cell in accordance with claim 1, wherein said grid insulator has a thickness through which charge carriers will tunnel with application across said grid insulator of a bias in a range of about 2 V to about 6 V.

18. A nonvolatile memory cell in accordance with claim 1, wherein the application of a positive bias from said conducting injector electrode with respect to said grid electrode will result in holes tunneling from said conducting injector electrode to said grid electrode.

19. A nonvolatile memory cell in accordance with claim 1, wherein application of a positive bias from said conducting injector electrode with respect to said grid electrode lowers a fermi level of said conducting injector electrode to cause holes to tunnel into said grid electrode with enough energy to pass into a valence band of said retention insulator.

20. A nonvolatile memory cell comprising:
a floating gate MOS transistor including:
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body; and
a floating gate dielectric disposed between said floating gate and said semiconductor body;
a tunneling electron injector including:
a first conducting injector electrode from which electrons are emitted;
a first grid insulator disposed adjacent to said first conducting injector electrode;
a first grid electrode disposed adjacent to said first grid insulator; and
a first retention insulator disposed adjacent to said first grid electrode,
wherein said floating gate is disposed adjacent to said first retention insulator and said first retention insulator has a first band gap in a first portion of said first retention insulator disposed adjacent to said first grid electrode, and a second, greater band gap in a second portion of said first retention insulator disposed between said first grid electrode and said floating gate;
a tunneling hole injector including:
a second conducting injector electrode from which holes are emitted;
a second grid insulator disposed adjacent to said second conducting injector electrode;
a second grid electrode disposed adjacent to said second grid insulator; and
a second retention insulator disposed adjacent to said second grid electrode,
wherein said second grid insulator comprises an oxygen-containing materials.

21. A nonvolatile memory cell in accordance with claim 20, wherein said oxygen-containing material comprises SiOₓN_{y} with an oxide fraction of less than about 77%.

22. A nonvolatile memory cell in accordance with claim 20, wherein said second conducting injector electrode comprises p+ doped silicon, and said second grid electrode comprises p+ doped silicon.

23. A nonvolatile memory cell in accordance with claim 22, wherein said oxygen-containing material comprises SiOₓN_{y} with an oxide fraction of less than about 77%.

24. A nonvolatile memory cell in accordance with claim 22, wherein said oxygen-containing material comprises a metal oxide.

25. A nonvolatile memory cell in accordance with claim 22, wherein said oxygen-containing material comprises one or more compounds selected from the group consisting of: BeO, MgO, ZrO₂, CaO, SrO, Y₂O₃, Pr₂O₃, ThO₂, ZrO₂ and Al₂O₃.

26. A nonvolatile memory cell in accordance with claim 20, wherein said floating gate is disposed adjacent to said second retention insulator and said second retention insulator has a first band gap in a first portion of said second retention insulator disposed adjacent to said second grid electrode, and a second, greater band gap in a second portion of said second retention insulator disposed between said second grid electrode and said floating gate.

27. A non volatile memory cell in accordance with claim 21, wherein said floating gate is disposed adjacent to said second retention insulator and said second retention insulator has a first band gap in a first portion of said second retention insulator disposed adjacent to said second grid electrode, and a second, greater band gap in a second portion of said second retention insulator disposed between said second grid electrode and said floating gate.

28. A nonvolatile memory cell in accordance with claim 22, wherein said floating gate is disposed adjacent to said second retention insulator and said second retention insulator has a first band gap in a first portion of said second retention insulator disposed adjacent to said second grid electrode, and a second, greater band gap in a second portion of said second retention insulator disposed between said second grid electrode and said floating gate.

29. A nonvolatile memory cell in accordance with claim 23, wherein said floating gate is disposed adjacent to said second retention insulator and said second retention insulator has a first band gap in a first portion of said second retention insulator disposed adjacent to said second grid electrode, and a second, greater band gap in a second portion of said second retention insulator disposed between said second grid electrode and said floating gate.

30. A nonvolatile memory cell in accordance with claim 24, wherein said floating gate is disposed adjacent to said second retention insulator and said second retention insulator has a first band gap in a first portion of said second retention insulator disposed adjacent to said second grid electrode, and a second, greater band gap in a second portion of said second retention insulator disposed between said second grid electrode and said floating gate.

31. A nonvolatile memory cell in accordance with claim 25, wherein said floating gate is disposed adjacent to said second retention insulator and said second retention insulator has a first band gap in a first portion of said second retention insulator disposed adjacent to said second grid electrode, and a second, greater band gap in a second portion of said second retention insulator disposed between said second grid electrode and said floating gate.

32. A nonvolatile memory cell in accordance with claim 20, wherein said floating gate has a conduction band edge and a valence band edge similar to a conduction band edge and a valence band edge of said first conducting injector electrode.

33. A nonvolatile memory cell in accordance with claim 20, wherein said floating gate comprises polysilicon.

34. A nonvolatile memory cell in accordance with claim 20, wherein said first retention insulator comprises a layer of silicon oxide having a thickness in a range of about 8 nm to about 50 nm.

35. A nonvolatile memory cell in accordance with claim 20, wherein said first grid electrode is thin enough to minimize loss of energy of injected charge carriers and thick enough to conduct away charge carriers that lose energy and are thermalized in said first grid electrode.

36. A nonvolatile memory cell in accordance with claim 20, wherein said first grid electrode has a thickness in a range of about 10 nm to about 50 nm.

37. A nonvolatile memory cell in accordance with claim 33, wherein said first grid electrode comprises a metal having a work function with a fermi level that in a flat band condition lies in approximately the middle of a band gap of said floating gate.

38. A nonvolatile memory cell in accordance with claim 20, wherein said first grid electrode comprises a metal selected from the group consisting of: Cr, Ni, Cu, W, Al, Ti, V, Zr, Mn, Nb, Ta and n-type silicon.

39. A nonvolatile memory cell in accordance with claim 20, wherein said first grid insulator comprises a layer of silicon oxide having a thickness in a range of about 2 nm to about 6 nm.

40. A nonvolatile memory cell in accordance with claim 20, wherein said first grid insulator has a thickness through which charge carriers will tunnel with application across said first grid insulator of a bias in a range of about 2 V to about 6 V.

41. A nonvolatile memory cell in accordance with claim 20, wherein said first conducting injector electrode comprises n-type doped silicon.

42. A nonvolatile memory cell in accordance with claim 41, wherein application of a negative bias from said first conducting injector electrode with respect to said first grid electrode will result in electrons tunneling from said first conducting injector electrode to said first grid electrode.

43. A nonvolatile memory cell in accordance with claim 41, wherein application of a negative bias from said first injector electrode with respect to said first grid electrode raises a conduction band of said first conducting injector electrode above a conduction band of said first retention insulator.

44. A nonvolatile memory cell in accordance with claim 22, wherein said second retention insulator has a thickness in a range of about 8 nm to about 50 nm.

45. A nonvolatile memory cell in accordance with claim 20, wherein said second grid electrode is thin enough to minimize loss of energy of injected charge carriers and thick enough to conduct away charge carriers that lose energy and are thermalized in said second grid electrode.

46. A nonvolatile memory cell in accordance with claim 22, wherein said second grid electrode has a thickness in a range of about 10 nm to about 50 nm.

47. A nonvolatile memory cell in accordance with claim 20, wherein said second grid insulator has a thickness through which charge carriers will tunnel with application across said second grid insulator of a bias in a range of about 2 V to about 6 V.

48. A nonvolatile memory cell in accordance with claim 20, wherein application of a positive bias from said second conducting injector electrode with respect to said second grid electrode will result in holes tunneling from said second conducting injector electrode to said second grid electrode.

49. A nonvolatile memory cell in accordance with claim 20, wherein application of a positive bias from said second conducting injector electrode with respect to said second grid electrode lowers a fermi level of said second conducting injector electrode below a valence band of said second retention insulator.

50. A nonvolatile memory cell in accordance with claim 20, wherein application of a positive bias from said second conducting injector electrode with respect to said second grid electrode lowers a valence band of said second conducting injector electrode below a valence band of said second retention insulator.

51. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling hole injector having a conducting injector electrode, a grid insulator disposed adjacent to said conducting injector electrode and comprising an oxygen-containing material, a grid electrode disposed adjacent to said grid insulator, and a retention insulator disposed adjacent to said grid electrode, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a plurality of source lines, at least one of said plurality of source lines coupled to said source region of each of said plurality of nonvolatile memory cells in a same row;
a plurality of injector lines, at least one of said plurality of injector lines coupled to said conducting injector electrode of each of said plurality of nonvolatile memory cells in a same row; and
a plurality of grid lines, at least one of said plurality of grid lines coupled to said grid electrode of each of said plurality of nonvolatile memory cells in a same column.

52. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling hole injector having a conducting injector electrode and comprising an oxygen-containing material, a grid insulator disposed adjacent to said conducting injector electrode, a grid electrode disposed adjacent to said grid insulator, and a retention insulator disposed adjacent to said grid electrode, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a plurality of injector lines, at least one of said plurality of injector lines coupled to said conducting injector electrode of each of said plurality of nonvolatile memory cells in a same column; and
a plurality of grid lines, at least one of said plurality of grid lines coupled to said grid electrode of each of said plurality of nonvolatile memory cells in a same row.

53. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling electron injector having a first conducting injector electrode, a first grid insulator disposed adjacent to said first conducting injector electrode, a first grid electrode disposed adjacent to said first grid insulator, and a first retention insulator disposed adjacent to said first grid electrode, wherein said floating gate is disposed adjacent to said first retention insulator and said first retention insulator has a first band gap in a first portion of said first retention insulator disposed adjacent to said first grid electrode, and a second, greater band gap in a second portion of said first retention insulator disposed between said first grid electrode and said floating gate;
a tunneling hole injector having a second conducting injector electrode, a second grid insulator disposed adjacent to said second conducting injector electrode and comprising an oxygen-containing material, a second grid electrode disposed adjacent to said second grid insulator, and a second retention insulator disposed adjacent to said second grid electrode, wherein said floating gate is disposed adjacent to said second retention insulator and said second retention insulator has a first band gap in a first portion of said second retention insulator disposed adjacent to said second grid electrode, and a second, greater, band gap in a second portion of said second retention insulator disposed between said second grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a plurality of source lines, at least one of said plurality of source lines coupled to said source region of each of said plurality of nonvolatile memory cells in a same row;
a first plurality of injector lines, at least one of said first plurality of injector lines coupled to said first conducting injector electrode of each of said plurality of nonvolatile memory cells in a same row;
a first plurality of grid lines, at least one of said first plurality of grid lines coupled to said first grid electrode of each of said plurality of nonvolatile memory cells in a same column;
a second plurality of injector lines, at least one of said second plurality of injector lines coupled to said second conducting injector electrode of each of said plurality of nonvolatile memory cells in a same row; and
a second plurality of grid lines, at least one of said second plurality of grid lines coupled to said second grid electrode of each of said plurality of nonvolatile memory cells in a same column.

54. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling electron injector having a first conducting injector electrode, a first grid insulator disposed adjacent to said first conducting injector electrode, a first grid electrode disposed adjacent to said first grid insulator, and a first retention insulator disposed adjacent to said first grid electrode, wherein said floating gate is disposed adjacent to said first retention insulator and said first retention insulator has a first band gap in a first portion of said first retention insulator disposed adjacent to said first grid electrode, and a second, greater band gap in a second portion of said first retention insulator disposed between said first grid electrode and said floating gate;
a tunneling hole injector having a second conducting injector electrode, a second grid insulator disposed adjacent to said second conducting injector electrode and comprising an oxygen containing materials a second grid electrode disposed adjacent to said second grid insulator, and a second retention insulator disposed adjacent to said second grid electrode, wherein said floating gate is disposed adjacent to said second retention insulator and said second retention insulator has a first band gap in a first portion of said second retention insulator disposed adjacent to said second grid electrode, and comprising an oxygen-containing material and a second, greater, band gap in a second portion of said second retention insulator disposed between said second grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a first plurality of injector lines, at least one of said first plurality of injector lines coupled to said first conducting injector electrode of each of said plurality of nonvolatile memory cells in a same column; and
a first plurality of grid lines, at least one of said first plurality of grid lines coupled to said first grid electrode of each of said plurality of nonvolatile memory cells in a same row.

55. A nonvolatile memory cell in accordance with claim 1, wherein said retention insulator further comprises a third portion disposed between said first portion and said second portion, said third portion having a graded band gap.

56. A nonvolatile memory cell in accordance with claim 1, wherein said retention insulator further comprises a third portion having a continuously graded band gap disposed between said first portion and said second portion.

57. A nonvolatile memory cell in accordance with claim 1, wherein said first portion of said retention insulator comprises a film formed of silicon oxide and said second portion of said retention insulator comprises a film formed of silicon oxinitride.

58. A nonvolatile memory cell in accordance with claim 1, wherein said retention insulator comprises a continuously graded band gap structure disposed between said first portion and said second portion of said retention insulator, said structure comprising SiOₓ and SiOₓN_{y}.

59. A nonvolatile memory cell in accordance with claim 16, further comprising:
a third portion of said first retention insulator disposed between said first portion and said second portion of said first retention insulator, said third portion of said first retention insulator having a graded band gap; and
a third portion of said second retention insulator disposed between said first portion and said second portion of said second retention insulator, said third portion of said second retention insulator having a graded band gap.

60. A nonvolatile memory cell in accordance with claim 20, further comprising:
a third portion of said first retention insulator having a continuously graded band gap disposed between said first portion and said second portion of said first retention insulator; and
a third portion of said second retention insulator having a continuously graded band gap disposed between said first portion and said second portion of said second retention insulator.

61. A nonvolatile memory cell in accordance with claim 20, wherein:
a first portion of said first retention insulator comprises a film formed of silicon oxide and said second portion of said first retention insulator comprises a film formed of silicon oxynitride; and
said first portion of said second retention insulator comprises a film formed of silicon oxide and said second portion of said second retention insulator comprises a film formed of silicon oxynitride.

62. A nonvolatile memory cell in accordance with claim 20, wherein:
said first retention insulator comprises a continuously graded band gap structure disposed between said first portion and said second portion of said first retention insulator, said structure comprising SiOₓ and SiOₓN_{y}; and
said second retention insulator comprises a continuously graded band gap structure disposed between said first portion and said second portion of said second retention insulator, said structure comprising SiOₓ and SiOₓN_{y}.

63. A nonvolatile memory cell in accordance with claim 51, further comprising a third portion disposed between said first portion and said second portion of said retention insulator, said third portion having a graded band gap.

64. A nonvolatile memory cell in accordance with claim 51, wherein said retention insulator further comprises a third portion having a continuously graded band gap disposed between said first portion and said second portion of said retention insulator.

65. A nonvolatile memory cell in accordance with claim 51, wherein said first portion of said retention insulator comprises a film formed of silicon oxide and said second portion of said retention insulator comprises a film formed of silicon oxynitride.

66. A nonvolatile memory cell in accordance with claim 53, wherein said retention insulator comprises a continuously graded band gap structure disposed between said first portion and said second portion of said retention insulator, said structure comprising SiOₓ and SiOₓN_{y}.

67. A nonvolatile memory cell in accordance with claim 53, further comprising:
a third portion of said first retention insulator disposed between said first portion and said second portion of said first retention insulator, said third portion of said first retention insulator having a graded band gap; and
a third portion of said second retention insulator disposed between said first portion and said second portion of said second retention insulator, said third portion of said second retention insulator having a graded band gap.

68. A nonvolatile memory cell in accordance with claim 53, further comprising:
a third portion of said first retention insulator having a continuously graded band gap disposed between said first portion and said second portion of said first retention insulator; and
a third portion of said second retention insulator having a continuously graded band gap disposed between said first portion and said second portion of said second retention insulator.

69. A nonvolatile memory cell in accordance with claim 53, wherein:
said first portion of said first retention insulator comprises a film formed of silicon oxide and said second portion of said first retention insulator comprises a film formed of silicon oxynitride; and
said first portion of said second retention insulator comprises a film formed of silicon oxide and said second portion of said second retention insulator comprises a film formed of silicon oxynitride.

70. A nonvolatile memory cell in accordance with claim 53, wherein:
said first retention insulator comprises a continuously graded band gap structure disposed between said first portion and said second portion of said first retention insulator, said structure comprising SiOₓ and SiOₓN_{y}; and
said second retention insulator comprises a continuously graded band gap structure disposed between said first portion and said second portion of said second retention insulator, said structure comprising SiOₓ and SiOₓN_{y}.

71. A nonvolatile memory cell comprising:
a floating gate MOS transistor including;
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body;
a floating gate dielectric disposed between said floating gate and said semiconductor body; and
a tunneling hole injector including:
a conducting injector electrode from which holes are emitted;
a grid insulator disposed adjacent to said conducting injector electrode;
a grid electrode disposed adjacent to said grid insulator; and
a retention insulator disposed adjacent to said grid electrode,
wherein charge carriers are ballistically injected from said charge injector through said retention insulator to said floating gate.

72. A nonvolatile memory cell comprising:
a floating gate MOS transistor including;
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body;
a floating gate dielectric disposed between said floating gate and said semiconductor body; and
a tunneling hole injector including:
a conducting injector electrode from which holes are emitted;
a grid insulator disposed adjacent to said conducting injector electrode;
a grid electrode disposed adjacent to said grid insulator; and
a retention insulator disposed adjacent to said grid electrode,
wherein charge carriers are ballistically injected from said charge injector through said retention insulator to said floating gate.

73. A nonvolatile memory cell comprising:
a floating gate MOS transistor including:
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body; and
a floating gate dielectric disposed between said floating gate and said semiconductor body;
a tunneling electron injector including:
a first conducting injector electrode from which electrons are emitted;
a first grid insulator disposed adjacent to said first conducting injector electrode;
a first grid electrode disposed adjacent to said first grid insulator; and
a first retention insulator disposed adjacent to said first grid electrode,
wherein said floating gate is disposed adjacent to said first retention insulator and said first retention insulator has a first band gap in a first portion of said first retention insulator disposed adjacent to said first grid electrode, and a second, greater band gap in a second portion of said first retention insulator disposed between said first grid electrode and said floating gate;
a tunneling hole injector including:
a second conducting injector electrode from which holes are emitted;
a second grid insulator disposed adjacent to said second conducting injector electrode;
a second grid electrode disposed adjacent to said second grid insulator; and
a second retention insulator disposed adjacent to said second grid electrode,
wherein charge carriers are ballistically injected from said respective injectors, through said respective retention insulators to said floating gate.

74. A nonvolatile memory cell comprising:
a floating gate MOS transistor including:
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body; and
a floating gate dielectric disposed between said floating gate and said semiconductor body;
a tunneling electron injector including:
a first conducting injector electrode from which electrons are emitted;
a first grid insulator disposed adjacent to said first conducting injector electrode;
a first grid electrode disposed adjacent to said first grid insulator; and
a first retention insulator disposed adjacent to said first grid electrode,
wherein said floating gate is disposed adjacent to said first retention insulator and said first retention insulator has a first band gap in a first portion of said first retention insulator disposed adjacent to said first grid electrode, and a second, greater band gap in a second portion of said first retention insulator disposed between said first grid electrode and said floating gate;
a tunneling hole injector including:
a second conducting injector electrode from which holes are emitted;
a second grid insulator disposed adjacent to said second conducting injector electrode;
a second grid electrode disposed adjacent to said second grid insulator; and
a second retention insulator disposed adjacent to said second grid electrode,
wherein said floating gate is disposed adjacent to said second retention insulator and said second retention insulator has a first band gap in a first portion of said second retention insulator disposed adjacent to said second grid electrode, and a second, greater band gap in a second portion of said second retention insulator disposed between said second grid electrode and said floating gate, and charge carriers are ballistically injected from said respective injectors, through said respective retention insulators to said floating gate.

75. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling charge injector having a conducting injector electrode, a grid insulator disposed adjacent to said conducting injector electrode, a grid electrode disposed adjacent to said grid insulator, and a retention insulator disposed adjacent to said grid electrode, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a plurality of source lines, at least one of said plurality of source lines coupled to said source region of each of said plurality of nonvolatile memory cells in a same row;
a plurality of injector lines, at least one of said plurality of injector lines coupled to said conducting injector electrode of each of said plurality of nonvolatile memory cells in a same row; and
a plurality of grid lines, at least one of said plurality of grid lines coupled to said grid electrode of each of said plurality of nonvolatile memory cells in a same column,
wherein charge carriers are ballistically injected from said charge injector through said retention insulator to said floating gate.

76. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling charge injector having a conducting injector electrode, a grid insulator disposed adjacent to said conducting injector electrode, a grid electrode disposed adjacent to said grid insulator, and a retention insulator disposed adjacent to said grid electrode, wherein said floating gate is disposed adjacent to said retention insulator and said retention insulator has a first band gap in a first portion of said retention insulator disposed adjacent to said grid electrode and a second, greater band gap in a second portion of said retention insulator disposed between said grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a plurality of injector lines, at least one of said plurality of injector lines coupled to said conducting injector electrode of each of said plurality of nonvolatile memory cells in a same column; and
a plurality of grid lines, at least one of said plurality of grid lines coupled to said grid electrode of each of said plurality of nonvolatile memory cells in a same row.

77. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling electron injector having a first conducting injector electrode, a first grid insulator disposed adjacent to said first conducting injector electrode, a first grid electrode disposed adjacent to said first grid insulator, and a first retention insulator disposed adjacent to said first grid electrode, wherein said floating gate is disposed adjacent to said first retention insulator and said first retention insulator has a first band gap in a first portion of said first retention insulator disposed adjacent to said first grid electrode, and a second, greater band gap in a second portion of said first retention insulator disposed between said first grid electrode and said floating gate;
a tunneling hole injector having a second conducting injector electrode, a second grid insulator disposed adjacent to said second conducting injector electrode, a second grid electrode disposed adjacent to said second grid insulator, and a second retention insulator disposed adjacent to said second grid electrode, wherein said floating gate is disposed adjacent to said second retention insulator and said second retention insulator has a first band gap in a first portion of said second retention insulator disposed adjacent to said second grid electrode, and a second, greater, band gap in a second portion of said second retention insulator disposed between said second grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a plurality of source lines, at least one of said plurality of source lines coupled to said source region of each of said plurality of nonvolatile memory cells in a same row;
a first plurality of injector lines, at least one of said first plurality of injector lines coupled to said first conducting injector electrode of each of said plurality of nonvolatile memory cells in a same row;
a first plurality of grid lines, at least one of said first plurality of grid lines coupled to said first grid electrode of each of said plurality of nonvolatile memory cells in a same column;
a second plurality of injector lines, at least one of said second plurality of injector lines coupled to said second conducting injector electrode of each of said plurality of nonvolatile memory cells in a same row; and
a second plurality of grid lines, at least one of said second plurality of grid lines coupled to said second grid electrode of each of said plurality of nonvolatile memory cells in a same column,
wherein charge carriers are ballistically injected from said respective injectors, through said respective retention insulators to said floating gate.

78. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling electron injector having a first conducting injector electrode, a first grid insulator disposed adjacent to said first conducting injector electrode, a first grid electrode disposed adjacent to said first grid insulator, and a first retention insulator disposed adjacent to said first grid electrode, wherein said floating gate is disposed adjacent to said first retention insulator and said first retention insulator has a first band gap in a first portion of said first retention insulator disposed adjacent to said first grid electrode, and a second, greater band gap in a second portion of said first retention insulator disposed between said first grid electrode and said floating gate;
a tunneling hole injector having a second conducting injector electrode, a second grid insulator disposed adjacent to said second conducting injector electrode, a second grid electrode disposed adjacent to said second grid insulator, and a second retention insulator disposed adjacent to said second grid electrode, wherein said floating gate is disposed adjacent to said second retention insulator and said second retention insulator has a first band gap in a first portion of said second retention insulator disposed adjacent to said second grid electrode, and comprising an oxygen-containing material and a second, greater, band gap in a second portion of said second retention insulator disposed between said second grid electrode and said floating gate;
a plurality of word lines, a separate one of said plurality of word lines coupled to said control gate of each of said plurality of nonvolatile memory cells in a same row;
a plurality of bit lines, a separate one of said plurality of bit lines coupled to said drain region of each of said plurality of nonvolatile memory cells in a same column;
a first plurality of injector lines, at least one of said first plurality of injector lines coupled to said first conducting injector electrode of each of said plurality of nonvolatile memory cells in a same column; and
a first plurality of grid lines, at least one of said first plurality of grid lines coupled to said first grid electrode of each of said plurality of nonvolatile memory cells in a same row,
wherein charge carriers are ballistically injected from said respective injectors, through said respective retention insulators to said floating gate.

79. A nonvolatile memory cell comprising:
a floating gate MOS transistor including:
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body;
a floating gate dielectric disposed between said floating gate and said semiconductor body;
a retention dielectric disposed over said floating gate;
a grid electrode disposed over said retention dielectric;
a tunnel dielectric disposed over said grid electrode; and
a tunneling charge injector disposed over said tunnel dielectric.

80. A nonvolatile memory cell in accordance with claim 79, wherein said first and second semiconductor regions are n+ doped.

81. A nonvolatile memory cell in accordance with claim 79, wherein said floating gate is disposed adjacent to said retention dielectric and said retention dielectric has a first band gap in a first portion of said retention dielectric disposed adjacent to said grid electrode and a second, greater band gap in a second portion of said retention dielectric disposed between said grid electrode and said floating gate.

82. A nonvolatile memory cell as in claim 79, wherein said floating gate comprises polysilicon.

83. A nonvolatile memory cell in accordance with claim 79, wherein said retention dielectric is formed of a layer of silicon oxide having a thickness in a range of about 8 nm to about 50 nm.

84. A nonvolatile memory cell in accordance with claim 79, wherein said grid electrode is thin enough to minimize loss of energy of injected charge carriers and thick enough to conduct away charge carriers that lose energy and are thermalized in said grid electrode.

85. A nonvolatile memory cell in accordance with claim 79, wherein said grid electrode has a thickness in a range of about 10 nm to about 50 nm.

86. A nonvolatile memory cell in accordance with claim 79, wherein the application of a positive bias from said injector with respect to said grid electrode will result in holes tunneling from said injector to said grid electrode.

87. A nonvolatile memory cell in accordance with claim 79, wherein application of a positive bias from said injector with respect to said grid electrode lowers a fermi level of said injector to cause holes to tunnel into said grid electrode with enough energy to pass into a valence band of said retention dielectric.

88. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling hole injector having a conducting injector electrode, a grid electrode, a tunnel dielectric disposed between said injector and said grid, and a retention insulator disposed between said grid and said floating gate;
a plurality of bit lines, a separate one of said plurality of bit lines coupled to said drain region of each of said plurality of nonvolatile memory cells in a same column;
a plurality of source lines, at least one of said plurality of source lines coupled to said source region of each of said plurality of nonvolatile memory cells in a same row;
a plurality of injector lines, at least one of said plurality of injector lines coupled to said conducting injector electrode of each of said plurality of nonvolatile memory cells in a same row; and
a plurality of grid lines, at least one of said plurality of grid lines coupled to said grid electrode of each of said plurality of nonvolatile memory cells in a same column.

89. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling hole injector having a conducting injector electrode, a grid electrode, a tunnel dielectric disposed between said injector and said grid, and a retention insulator disposed between said grid and said floating gate;
a plurality of bit lines, a separate one of said plurality of bit lines coupled to said drain region of each of said plurality of nonvolatile memory cells in a same column;
a plurality of injector lines, at least one of said plurality of injector lines coupled to said conducting injector electrode of each of said plurality of nonvolatile memory cells in a same column; and
a plurality of grid lines, at least one of said plurality of grid lines coupled to said grid electrode of each of said plurality of nonvolatile memory cells in a same row.

90. A nonvolatile memory cell comprising:
a floating gate MOS transistor including;
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body;
a floating gate dielectric disposed between said floating gate and said semiconductor conductor body; and
a tunneling hole injector including:
a conducting injector electrode from which holes are emitted;
a grid electrode;
a tunnel dielectric disposed between said grid and said injector; and
a retention insulator disposed between said grid and said floating gate,
wherein charge carriers are ballistically injected from said charge injector through said retention insulator to said floating gate.

91. A nonvolatile memory cell comprising:
a floating gate MOS transistor including;
a semiconductor body having a doping of a first type;
first and second semiconductor regions having a doping of a second type, said first and second semiconductor regions spaced apart to form a channel region in between said first and second semiconductor regions in said semiconductor body;
a floating gate disposed above said channel region in said semiconductor body;
a floating gate dielectric disposed between said floating gate and said semiconductor conductor body; and
a tunneling hole injector including:
a conducting injector electrode from which holes are emitted;
a grid electrode;
a tunnel dielectric disposed between said grid and said injector; and
a retention insulator disposed between said grid and said floating gate,
wherein charge carriers are ballistically injected from said charge injector through said retention insulator to said floating gate.

92. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling charge injector having a conducting injector electrode, a grid electrode, a tunnel dielectric disposed between said injector and said grid, and a retention insulator disposed between said grid and said floating gate;
a plurality of bit lines, a separate one of said plurality of bit lines coupled to said drain region of each of said plurality of nonvolatile memory cells in a same column;
a plurality of source lines, at least one of said plurality of source lines coupled to said source region of each of said plurality of nonvolatile memory cells in a same row;
a plurality of injector lines, at least one of said plurality of injector lines coupled to said conducting injector electrode of each of said plurality of nonvolatile memory cells in a same row; and
a plurality of grid lines, at least one of said plurality of grid lines coupled to said grid electrode of each of said plurality of nonvolatile memory cells in a same column,
wherein charge carriers are ballistically injected from said charge injector through said retention insulator to said floating gate.

93. A nonvolatile memory device comprising:
a plurality of nonvolatile memory elements arranged in a rectangular array of rows and columns, each of said plurality of nonvolatile memory elements including:
a floating gate MOS transistor having a source region and a drain region formed in a semiconductor body and spaced apart by a channel region, and a floating gate disposed above said channel region; and
a tunneling charge injector having a conducting injector electrode, a grid electrode, a tunnel dielectric disposed between said injector and said grid, and a retention insulator disposed between said grid and said floating gate;
a plurality of bit lines, a separate one of said plurality of bit lines coupled to said drain region of each of said plurality of nonvolatile memory cells in a same column;
a plurality of injector lines, at least one of said plurality of injector lines coupled to said conducting injector electrode of each of said plurality of nonvolatile memory cells in a same column; and
a plurality of grid lines, at least one of said plurality of grid lines coupled to said grid electrode of each of said plurality of nonvolatile memory cells in a same row.
